(19) United States
(12) Patent Application Publication
(10) Pub. No.: US 2026/0334177 A1
(43) Pub. Date: Oct. 22, 2026

(54) STI PROTECTION LAYER FORMATION THROUGH IMPLANTATION AND THE STRUCTURES THEREOF

(71) Applicant: Taiwan Semiconductor Manufacturing Co., Ltd., Hsinchu (TW)

(72) Inventors: Bau-Ming Wang, Kaohsiung City (TW); Chia-Cheng Chen, Hsinchu (TW); Chien-Hao Chen, Chuangwei Township (TW); Meng-Han Chou, Hsinchu (TW); Wei-Ting Chang, Hsinchu (TW); Su-Hao Liu, Jhongpu Township (TW)

(21) Appl. No.: 19/721,101

(22) Filed: Jun. 26, 2026

Related U.S. Application Data
(63) Continuation of application No. 18/917,352, filed on Oct. 16, 2024.
(60) Provisional application No. 63/660,655, filed on Jun. 17, 2024.

(51) Int. Cl. H10W 10/00; H10D 30/01; H10D 30/43; H10D 30/67; H10D 62/10; H10D 62/13; H10D 64/01; H10W 10/17

(52) U.S. Cl. CPC H10W 10/014; H10D 30/014; H10D 30/43; H10D 30/6735; H10D 30/6757; H10D 62/121; H10D 62/151; H10D 64/015; H10D 64/017; H10D 64/018; H10W 10/17

(57) ABSTRACT

A method includes forming a shallow trench isolation region aside of a protruding fin. The protruding fin includes a first semiconductor nanostructure and a second semiconductor nanostructure. The method further includes forming a dielectric layer on the shallow trench isolation region, forming a dummy gate stack over the protruding fin, and performing an implantation process to form a protection layer. The protection layer covers the shallow trench isolation region. A sacrificial layer in the protruding fin is removed to leave a space between the first semiconductor nanostructure and the second semiconductor nanostructure. A disposable interposer is formed in the space. The dummy gate stack is then removed, followed by performing an etching process to remove the disposable interposer, and forming a replacement gate stack, wherein a portion of the replacement gate stack is filled in the space.

### PRIORITY CLAIM AND CROSS-REFERENCE

This application is a continuation of U.S. patent application Ser. No. 18/917,352, filed Oct. 16, 2024 and entitled “STI PROTECTION LAYER FORMATION THROUGH IMPLANTATION AND THE STRUCTURES THEREOF,” which claims the benefit of U.S. Provisional Application No. 63/660,655, filed on Jun. 17, 2024, and entitled “STI OXIDE ETCHING STOP LAYER FORMATION FOR DOI PROCESS BY ION IMPLANTATION,” which application are hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3A, 3B through 18A, 18B, and 18C illustrate the views of intermediate stages in the formation of transistors and STI protection layers in accordance with some embodiments.

FIG. 19 illustrates a process flow for forming transistors in accordance with some embodiments.

FIGS. 20A, 20B, and 20C through 33A, 33B, and 33C illustrate the views of intermediate stages in the formation of transistors and STI protection layers in accordance with some embodiments.

FIG. 34 illustrates a process flow for forming transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Gate-All-Around (GAA) transistors, shallow trench isolation protection layers and the methods of forming the same are provided. In accordance with some embodiments of the present disclosure, the formation of the GAA transistor adopts Disposable Oxide Interposing (DOI) processes, which include forming sacrificial layers comprising oxides. Since the sacrificial layers may not have enough etching selectivity relative to Shallow Trench Isolation (STI) regions, the STI regions may be undesirable recessed. This may cause the undesirable increase in effective capacitance Ceff between conductive features, and the undesirable increase of out fringe capacitance. A protection layer (also referred to as a hard mask) is thus formed through implantation to prevent the STI regions from being recessed during the removal of the sacrificial layers.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

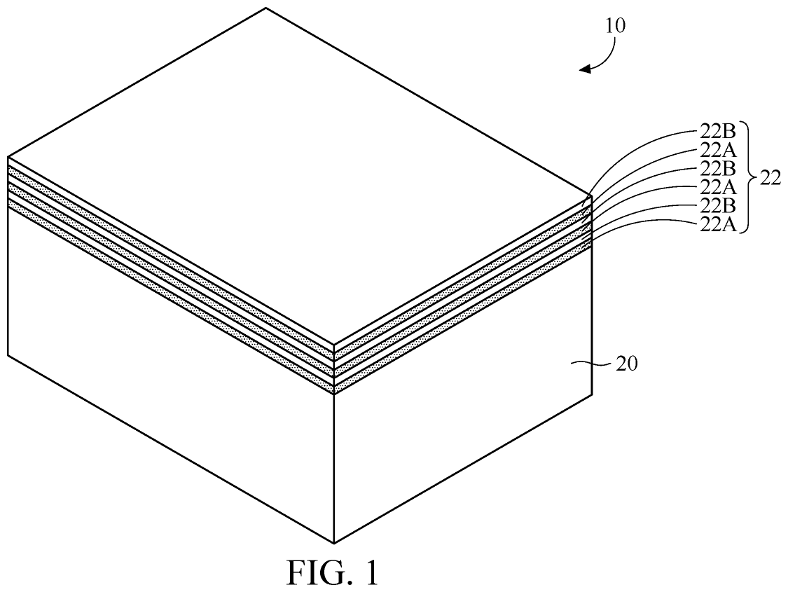

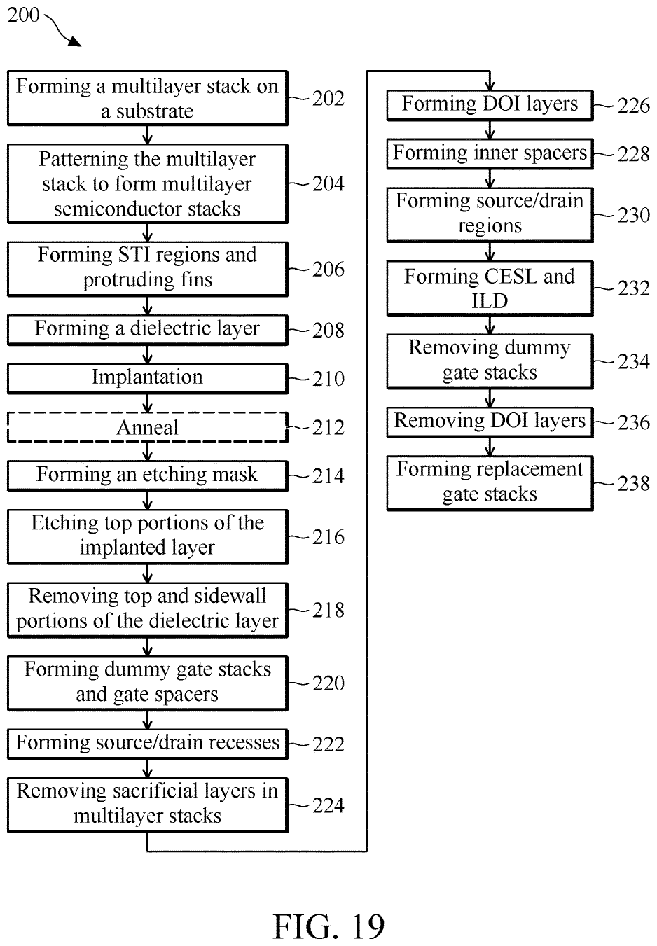

FIG. 1 through FIGS. 18A, 18B, and 18C illustrate the cross-sectional views of intermediate stages in the formation of an GAA transistor in accordance with some embodiments of the present disclosure. The corresponding processes are also reflected schematically in the process flow 200 as shown in FIG. 19.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 as shown in FIG. 19. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22B may be formed to a second thickness in the range between about 10 Å and about 500 Å, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there are some pad oxide layer(s) and hard mask layer(s) (not shown) formed over multilayer stack 22. These layers are patterned, and are used for the subsequent patterning of multilayer stack 22.

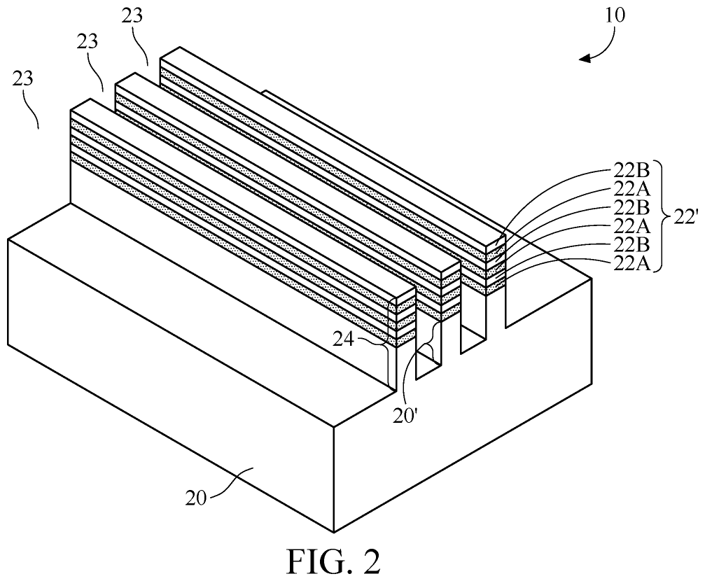

Referring to FIG. 2, multilayer stack 22 and a portion of the underlying substrate 20 are patterned in an etching process(es), so that trenches 23 are formed. The respective process is illustrated as process 204 in the process flow 200 as shown in FIG. 19. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

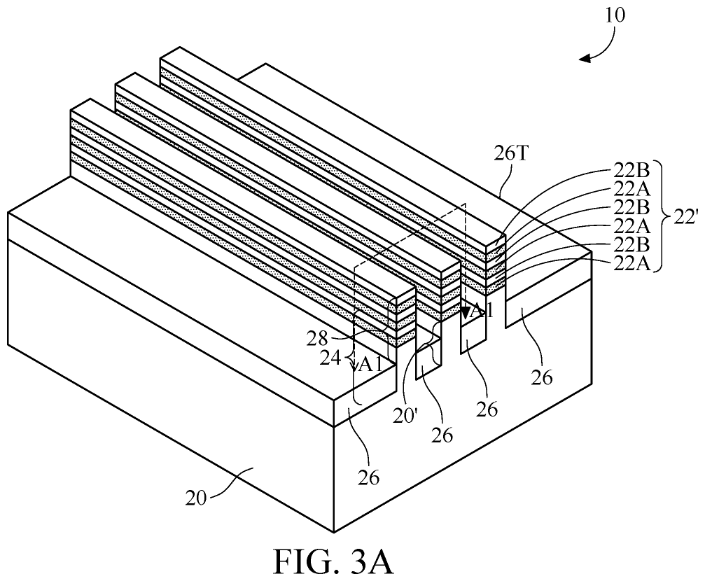

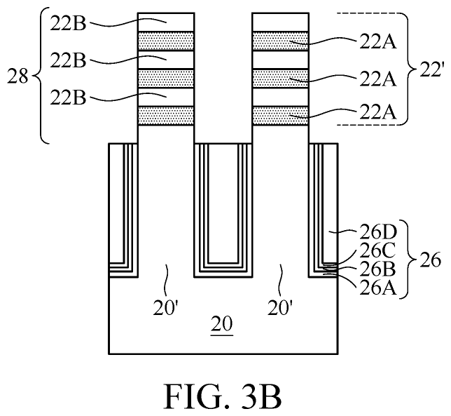

FIG. 3A illustrates the formation of isolation regions 26, which are also referred to as Shallow Trench Isolation (STI) regions throughout the description. The respective process is illustrated as process 206 in the process flow 200 as shown in FIG. 19. STI regions 26 may include a liner oxide (not shown), which may be a thermal oxide formed through the thermal oxidation of a surface layer of substrate 20, or may be deposited. The liner oxide may also be a deposited silicon oxide layer formed using, for example, ALD, High-Density Plasma Chemical Vapor Deposition (HDPCVD), CVD, or the like.

STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20'. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

FIG. 3B illustrates a cross-section A1-A1 in FIG. 3A. As shown in FIG. 3B, STI regions 26 may include a plurality of dielectric liners such as dielectric liners 26A, 26B, and 26C, and dielectric region 26D on dielectric liners 26C. In accordance with some embodiments, dielectric liner 26A is formed of or comprises silicon oxide, which may be formed through a thermal oxidation process or a deposition process. Dielectric liners 26B and 26C may be formed of silicon nitride or silicon oxide.

Dielectric region 26D may be formed of or comprise silicon oxide. Dielectric region 26D may have a lower density and a higher etching rate than dielectric liners 26A, 26B, and 26C. For example, when dielectric region 26D is formed of FCVD, spin-on coating, or the like, it may have a lower density than the dielectric liners 26A, 26B, and 26C. Dielectric region 26D may also be formed through another deposition process such as ALD, CVD, or the like.

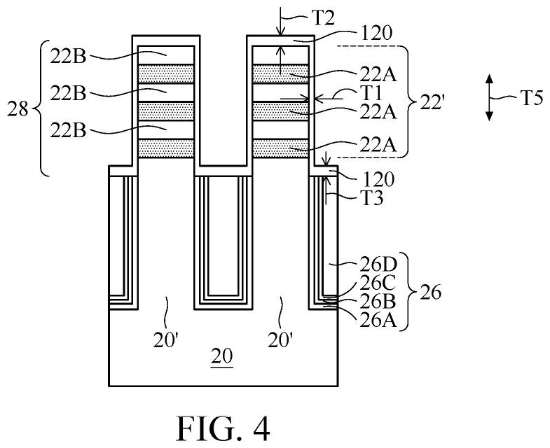

Referring to FIG. 4, dielectric layer 120 is formed. The respective process is illustrated as process 208 in the process flow 200 as shown in FIG. 19. In accordance with some embodiments, dielectric layer 120 comprises silicon oxide. In accordance with other embodiments, dielectric layer 120 may comprise other materials such as SiC, SiON, SiCN, SiOCN, or the like. In accordance with some embodiments, the thickness of dielectric layer 120 is in the range between about 1 nm and about 20 nm.

In accordance with some embodiments, dielectric layer 120 is formed as a non-conformal layer with the sidewall portions having thickness T1, top portions having thickness T2, and bottom portions having thickness T3. In accordance with some embodiments, thicknesses T2 and T3 are greater than thickness T1. In accordance with some embodiments, thickness T3 is greater than thickness T2, which is further greater than thickness T1. The difference between thicknesses T1, T2, and T3 may be achieved by adjusting the process conditions of the deposition process, for example, with a bias power applied during the deposition process. The deposition process may include CVD, Plasma-Enhanced Chemical Vapor Deposition (PECVD) or the like. With the bottom portion having a greater thickness, the thickness of the subsequently formed protection layer 126 may be advantageously increased.

In accordance with alternative embodiments, the formation may include a deposition process, which may be a conformal deposition process such as ALD, CVD, or the like. The dielectric layer 120 is thus a conformal layer with thicknesses T1, T2, and T3 having a same value.

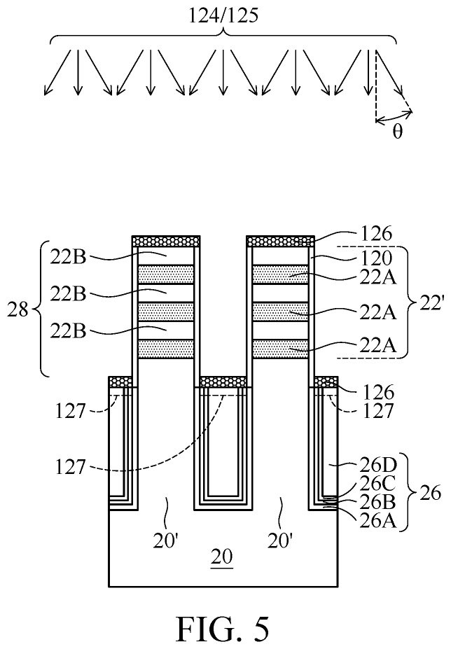

Referring to FIG. 5, an implantation process 124 is performed. The respective process is illustrated as process 210 in the process flow 200 as shown in FIG. 19. The implanted element (alternatively referred to as dopant or species) may include carbon and/or nitrogen. In addition, silicon may be implanted. Silicon may be implanted along with carbon and/or nitrogen. The silicon may also be implanted before, after, or in the same implantation process as the implantation of carbon and/or nitrogen. In addition, some other elements such as He, Ar, oxygen, and the like may be implanted, and may be implanted when (or before or after) the Si, O, C, N, He, Ar, and/or the like are implanted.

In accordance with some embodiments, the implantation process 124 may be performed through a vertical implantation process and/or a tilt implantation process. When the tilt implantation process is performed, the tilt angle θ may greater than 0 degrees and smaller than about 60 degrees.

As a result of the implantation process 124, the bottom portion of dielectric layer 120 is converted as protection layer 126, which has a higher dopant (such as Si, carbon, nitrogen, oxygen, and/or He) concentration (and atomic percentages) than before the implantation process. The dopant concentration may also be higher than the un-implanted portions of dielectric layer 120 and the underlying un-implanted portions of STI regions 26. Depending on the implanted species, the protection layer 126 may include SiOC, SiON, SiOCN, or the like, with other elements such as He incorporated.

In accordance with some embodiments, the implantation energy is controlled, so that the dielectric layer 120 is implanted, while the top semiconductor nanostructure 22B is not implanted. Alternatively, the top semiconductor nanostructure 22B is implanted with a significantly lower dosage than in protection layer 126 due to the dopant distribution at different depths. In accordance with some embodiments, the implanted species such as Si, C, N, O, He, and the like may each be implanted with an energy in a range between about 1 keV and about 20 keV. The dosage of each of the above listed species and/or the total dosage of the implanted species may be in the range between about 5E13/cm² and 1E16/cm². The concentration of the implanted species may be in the range between about 1E20/cm³ and about 3E22/cm³.

The implantation process 124 may be performed at room temperature (for example, about 18 °C to about 22 °C), or at an elevated temperature to reduce the damage to the implanted regions. For example, the implantation may be performed at a temperature in a range between the room temperature and about 600 °C, and may be in the range between about 50 °C and about 600 °C .

In accordance with some embodiments, at the time during the implantation process 124, the pad oxide layer and the hard mask (not shown) that are used for patterning multi-layer stack 22 remain, and are left over the top surface of the top semiconductor nanostructure 22B. Accordingly, the pad oxide layer and the hard mask protects the top semiconductor nanostructure 22B from being implanted. The implantation energy may thus be increased without the concern of damaging the top semiconductor nanostructure 22B. As a result, some top portions of the STI regions 26 are also implanted. The dashed lines 127 schematically illustrate the bottoms the corresponding protection layer 126 in accordance with these embodiments.

In accordance with some embodiments in which vertical implantation is adopted, dielectric layer 120 is thick, and the thickness T1 of vertical portions of dielectric layer 120 is greater than the thickness T4 of the vertical portion of dielectric liner 26A. Accordingly, in the implantation process 124, dielectric liner 26A is masked from being implanted, and is not convert into a part of protection layer 126, as shown in FIG. 5.

In accordance with alternative embodiments, for example, when implantation process 124 comprises a tilt implantation process, and/or the implanted species is diffused into the vertical portions of dielectric liner 26A, protection layer 126 will also include the top parts of the vertical portions of dielectric liner 26A.

In accordance with alternative embodiments, before the formation of dielectric layer 120, the pad oxide layer and the hard mask are removed. Accordingly, the thicknesses of protection layer 126 are used to control the implantation process 124, so that the top semiconductor nanostructure 22B is not implanted or substantially not implanted, for example, with the doping concentration lower than that in protection layer 126 by two orders or more.

In accordance with some embodiments, after the implantation process 124, an anneal process 125 is performed to recover the structure of the implanted regions, so that the damage caused by the implantation process 124 is reduced or eliminated. The respective process is illustrated as process 212 in the process flow 200 as shown in FIG. 19.

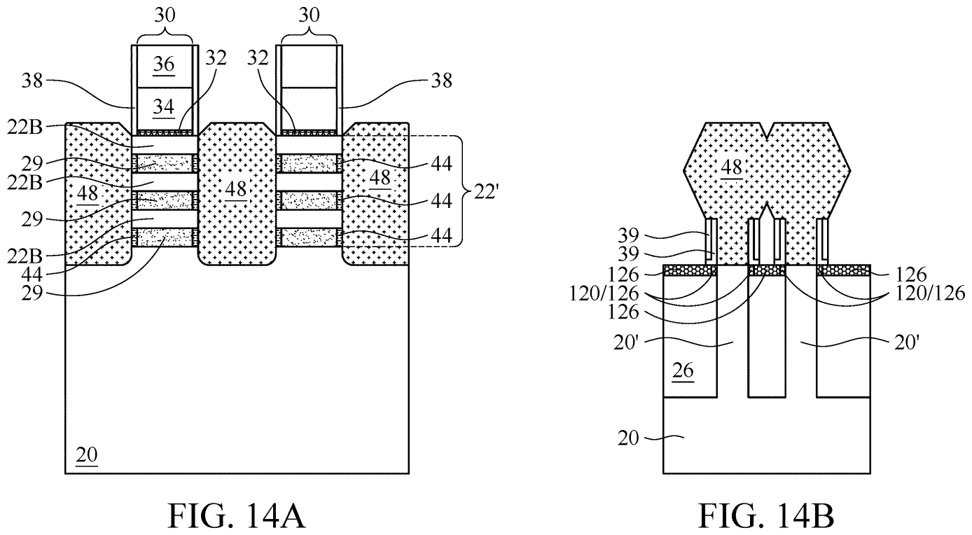

In accordance with alternative embodiments, the anneal process 125 is not performed. Rather, the recovery of the implanted regions is achieved by subsequent thermal processes. Accordingly, the process 212 in FIG. 19 is shown as being dashed to indicate the anneal process 125 may or may not be performed. For example, a source/drain anneal process may be performed after the formation of source/drain regions 48 (FIGS. 14A and 14B). The source/drain anneal process may be performed at a temperature in the range between about 1,000 °C and about 1,200 °. The annealing duration may be in the range between about 1 millisecond and about 2 milliseconds.

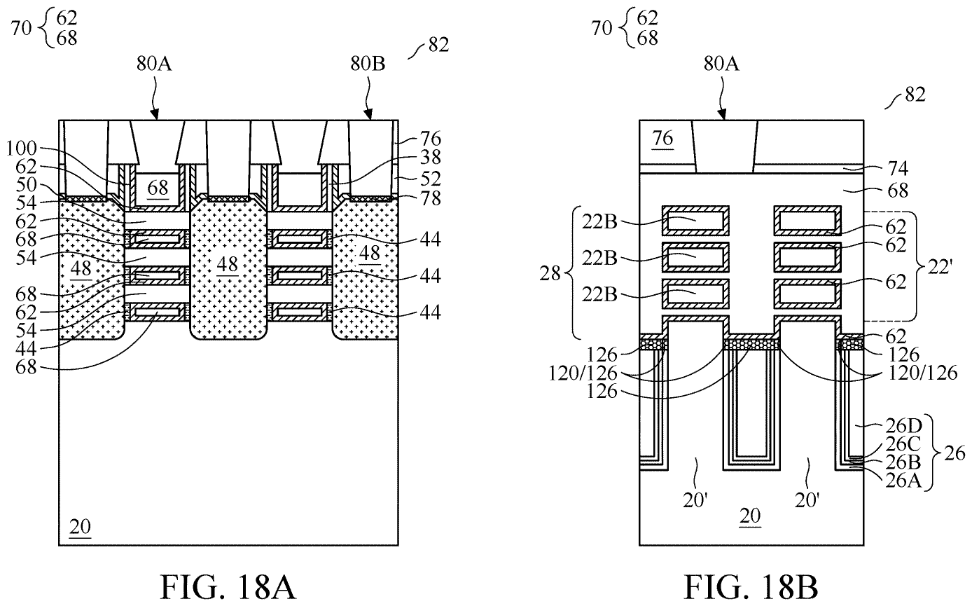

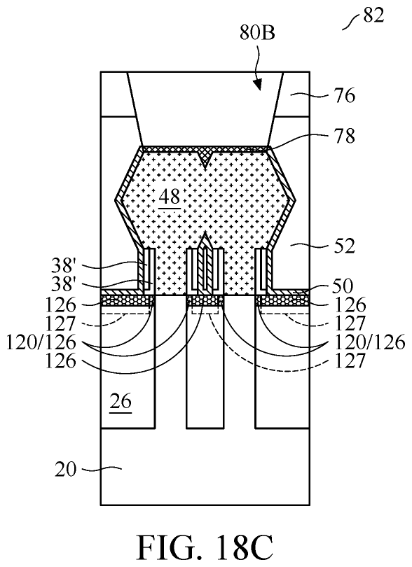

Alternatively, the recovery of the implanted regions may be performed by the process of annealing inter-layer dielectrics (ILDs) such as ILDs 52 and/or 76 (FIGS. 18B and 18C). The ILD anneal process may be performed at a temperature in the range between about 500 °C and about 600°. The annealing duration may be in the range between about 1 hour and 2 hours.

In accordance with some embodiments, the anneal process 125 (if performed) may be performed at a wafer temperature in the range between about 500 °C and about 1,200 °C. The annealing duration may depend on the temperature, and may be in the range between about 1 millisecond and about 2 hours. For example, when a high anneal temperature is adopted such as in the range between about 1,000°C and about 1,200°, the anneal duration may be short such as in the range between about 1 millisecond and about 2 milliseconds. When a low anneal temperature is adopted such as in the range between about 500 °C and about 600°, the anneal duration may be long such as in the range between about 1 hour and about 2 hours.

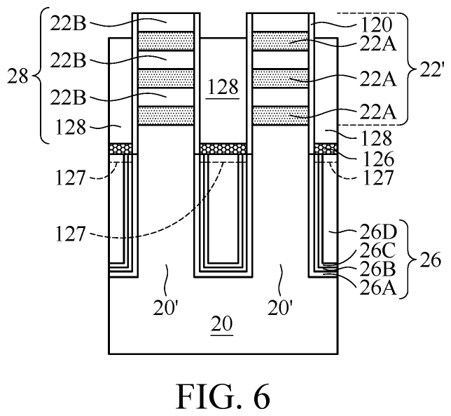

FIG. 6 illustrates the formation of sacrificial layer 128, which is used as an etching mask. The respective process is illustrated as process 214 in the process flow 200 as shown in FIG. 19. In accordance with some embodiments, sacrificial layer 128 includes a material that may be used as a Bottom Anti-Reflective Coating (BARC), and may include a cross-linked photoresist, SiOC, or the like. The formation of sacrificial layer 128 may include a deposition (or dispensing) process, followed by a planarization process, and then an etch-back process. The top portions of the implanted portions of dielectric layer 120 are thus exposed.

FIG. 6 further illustrates an etching process to remove some top portions of the implanted portions of dielectric layer 120. The respective process is illustrated as process 216 in the process flow 200 as shown in FIG. 19. The etching chemical is selected to have a low etching rate on dielectric layer 120. The etching may be performed through a dry etching process, a wet etching process, or the like.

In accordance with some embodiments, the etching gas may include a fluorine-containing gas such as CF₄, NF₃, SF₆, CHF₃, ClF₃, or the like, or combinations thereof. Other gases such as O₂, N₂, H₂, Ar, NO, and the like, may also be added. In accordance with alternative embodiments, a wet etching process may be adopted, for example, using H₃PO₄. After the etching process, the top portion of the implanted portions of dielectric layer 120 may be fully removed, or may have a thin portion remaining.

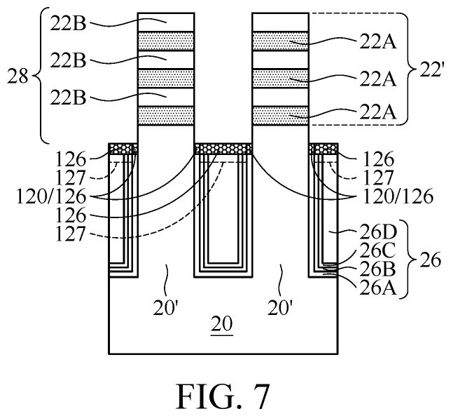

The sacrificial layer 128 is then removed, followed by an etching process to remove the sidewall portions of dielectric layer 120. The respective process is illustrated as process 218 in the process flow 200 as shown in FIG. 19. The resulting structure is shown in FIG. 7. Protection layer 126 is thus revealed. The etching chemical for etching dielectric layer 120 is selected to have a low etching rate on protection layer 126. The etching may be performed through a dry etching process, wherein the mixture of NF₃ and NH₃, the mixture of HF and NH₃, or the like may be used. When a wet etching process, is used, a diluted HF solution may be used as the etching chemical.

In the embodiments in which tilt implantation is performed, the sidewall portions of dielectric layer 120 are also implanted. The sidewall portions of dielectric layer 120 are thinner than the respective top and bottom portions. The etching process is controlled, so that the sidewall portions of dielectric layer 120 are fully removed, while the bottom portions of the implanted dielectric layer 120 have at least some portions remaining as the protection layer 126.

In accordance with some embodiments in which the implantation process comprises a tilt implantation process, all of the dielectric layer 120 may be converted as protection layer 126. Accordingly, in FIG. 7, the symbol “126/120” is used to represent that the features pointed to by the symbol “126/120” may be the remaining portions of the dielectric layer 120 that are not implanted, or may be the portions that are implanted to form parts of protection layers 126. Accordingly, protection layer 126 may be spaced apart from semiconductor strips 20′ by remaining un-implanted portions of dielectric layer 120, or may extend to and in physical contact with the sidewalls of semiconductor strips 20′.

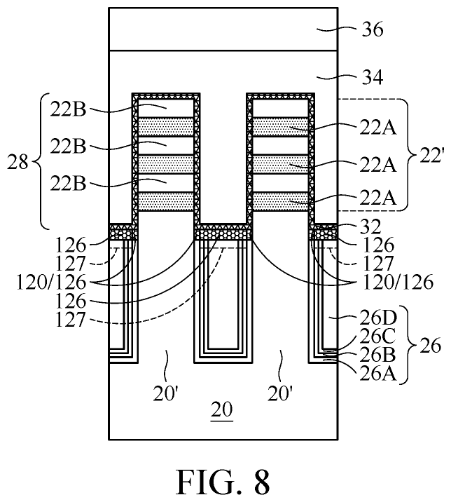

In subsequent processes, dummy gate stacks and gate spacers are formed. FIG. 8 illustrates the formation of dummy gate dielectric layer 32 (also referred to as dummy gate dielectric 32), dummy gate electrode layer 34 (also referred to as dummy gate electrode 34), and hard mask layer 36 (also referred to as hard mask 36). Dummy gate dielectrics 32 may be formed by oxidizing the surface portions of protruding fins 28 to form oxide layers, or by depositing a dielectric layer such as a silicon oxide layer. Dummy gate electrode layer 34 may be formed, for example, by depositing polysilicon or amorphous silicon, and other materials such as amorphous carbon may also be used. A planarization process may be performed to level the top surface of dummy gate electrode layer 34.

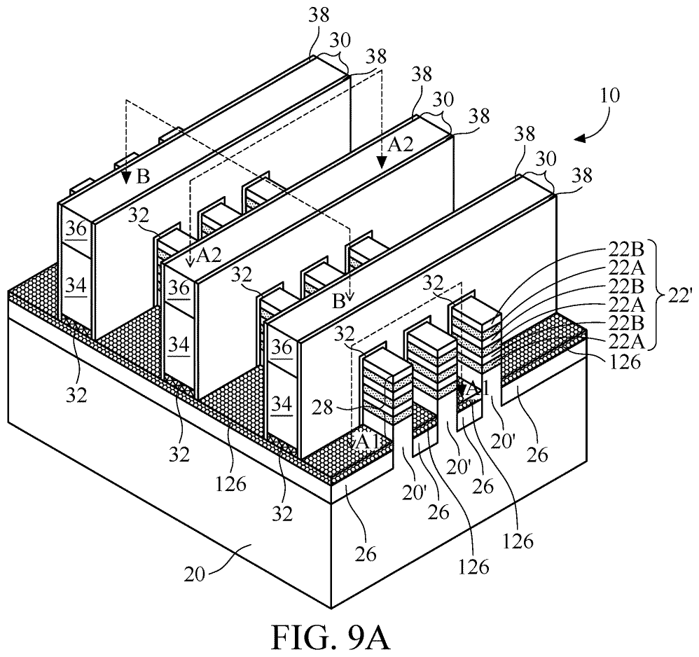

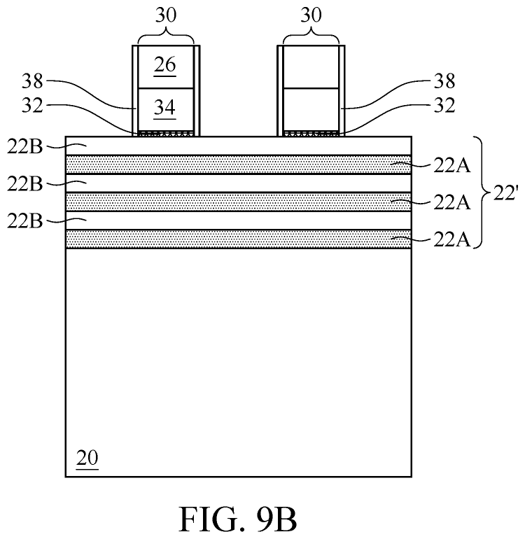

Hard mask layer 36 may be formed through deposition over dummy gate electrode layer 34. Hard mask layer 36 may be formed of silicon nitride, silicon oxide, silicon carbo-nitride, silicon oxy-carbo nitride, or multilayers thereof. A patterning process(es) are then performed to form a plurality of dummy gate stacks 30 as shown in FIG. 9A, which illustrates a perspective view of the structure. The respective process is illustrated as process 220 in the process flow 200 as shown in FIG. 19.

Next, as also shown in FIG. 9A, gate spacers 38 are formed on the sidewalls of dummy gate stacks 30. The respective process is also illustrated as process 220 in the process flow 200 as shown in FIG. 19. In accordance with some embodiments of the present disclosure, gate spacers 38 are formed of a dielectric material such as silicon nitride (SiN), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

It is appreciated that although each of the gate spacers 38 is illustrated as being a single layer, gate spacers 38 may be multi-layer spacers. Since gate spacers 38 may be formed sharing common processes as fin spacers 39, gate spacers 38 may have the same structure as fin spacers 39 (FIG. 18C). For example, gate spacers 38 may include a first layer having an L-shape in a cross-sectional view, and a second layer (which is formed of a different material than the first layer) on a horizontal leg of the first layer.

As show in FIG. 9A, protection layer 126 includes the portions that are directly under and overlapped by dummy gate stacks 30, and the portions that are not directly under dummy gate stacks 30. FIG. 9B illustrates a cross-sectional view of the cross-section B-B as shown in FIG. 9A.

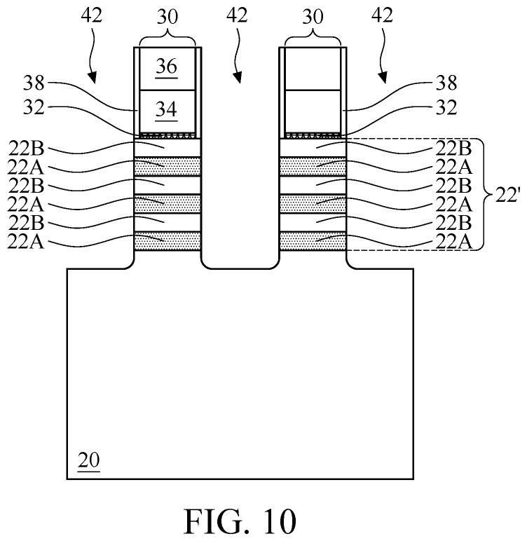

FIG. 10 illustrates a source/drain recessing process. The respective process is illustrated as process 222 in the process flow 200 as shown in FIG. 19. The protruding fins 28 that are not directly underlying dummy gate stacks 30 and gate spacers 38 are etched in an anisotropic etching process. Source/drain recesses 42 are thus formed.

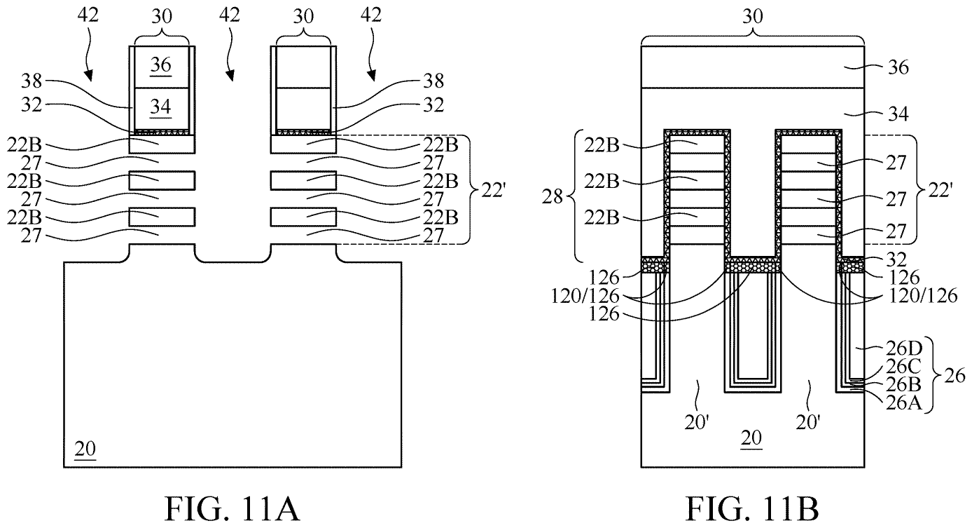

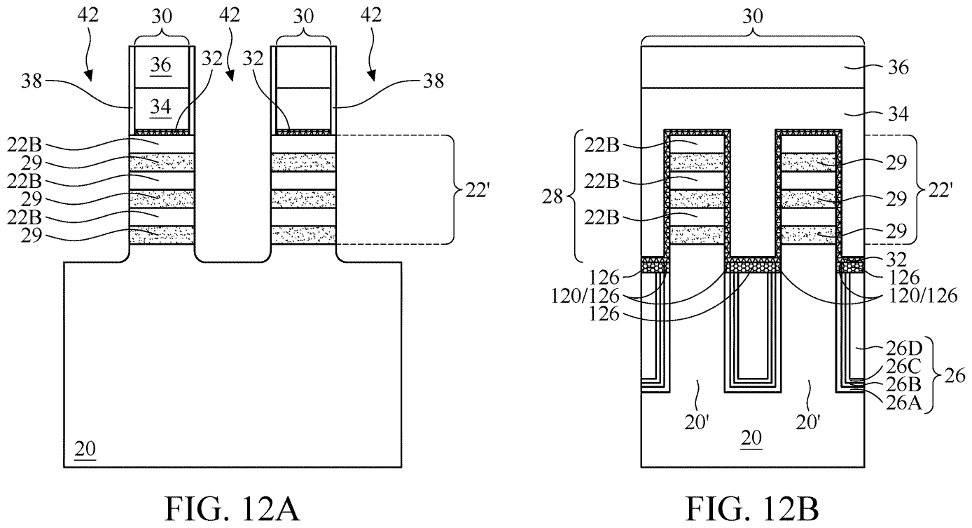

FIGS. 11A, 11B, 12A, and 12B illustrate the replacement of sacrificial layers 22A with disposable interposers 29. Referring to FIGS. 11A and 11B, which illustrate the cross-sections B-B and A2-A2, respectively in FIG. 9A, the sacrificial layers 22A are first removed, forming openings 27 between nanostructures 22B. The respective process is illustrated as process 224 in the process flow 200 as shown in FIG. 19.

Referring to FIGS. 12A and 12B, disposable interposers 29 are formed between nanostructures 22B. The respective process is illustrated as process 226 in the process flow 200 as shown in FIG. 19. In accordance with some embodiments, disposable interposers 29 comprise an oxide such as silicon oxide, and thus may also be referred to as Disposable Oxide Interposers (DOIs) 29. In accordance with other embodiments, disposable interposers 29 may comprise other types of dielectric materials such as AlO, SiON, SiC, SiCN, or the like.

The formation of disposable interposers 29 may include depositing a dielectric layer using a conformal deposition process, so that the dielectric layer includes some portions filling openings 27, and some other portions outside of openings 27. A trimming process, which may include an isotropic etching process, or the combination of an anisotropic etching process followed by an isotropic etching process, is then performed to etch and remove the portions of the dielectric layer outside of openings 27. The remaining portions of the dielectric layer are thus the disposable interposers 29.

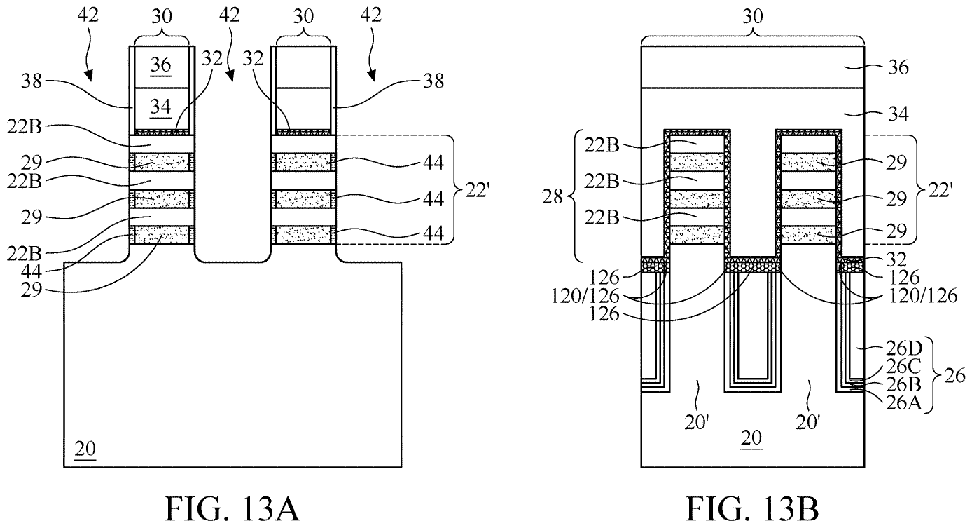

Referring to FIGS. 13A and 13B, disposable interposers 29 are laterally recessed and filled to form inner spacers 44 (FIG. 13A). The respective process is illustrated as process 228 in the process flow 200 as shown in FIG. 19. The lateral recessing of disposable interposers 29 may be achieved through a wet etching process or a dry etching process. The wet etching process may be performed using a dip process, a spray process, a spin-on process, or the like. Nanostructures 22B are not etched.

Inner spacers 44 are then formed. In accordance with some embodiments, the formation of inner spacers 44 includes depositing a conformal dielectric layer, which extends into the lateral recesses. Next, an etching process (also referred to as a spacer trimming process) is performed to trim the portions of the dielectric layer outside of the lateral recesses, leaving the portions of the dielectric layer in the lateral recesses. The remaining portions of the dielectric layer are referred to as inner spacers 44.

Referring to FIGS. 14A and 14B, which illustrate the same cross-sections as the cross-sections B-B and A1-A1, respectively in FIG. 9A, epitaxial source/drain regions 48 are formed in recesses 42 through selective epitaxy. The respective process is illustrated as process 230 in the process flow 200 as shown in FIG. 19. Fin spacers 39 may have a multi-layer structure. For example, a fin spacer layer 39 may include a first layer having an L-shape in a cross-section, and a second layer (which is formed of a different material than the first layer) on a horizontal leg of the first layer. Fin spacers 39 are also illustrated, which may share common deposition processes as, and hence may have the same structure and same sub-layers as, gate spacers 38.

Depending on whether the resulting transistor is a p-type transistor or an n-type transistor, a p-type or an n-type impurity may be in-situ doped with the proceeding of the epitaxy. For example, when the resulting transistor is a p-type Transistor, silicon germanium boron (SiGeB), silicon boron (SiB), or the like may be grown. Conversely, when the resulting transistor is an n-type Transistor, silicon phosphorous (SiP), silicon arsenic (SiAs), silicon carbon phosphorous (SiCP), or the like may be grown.

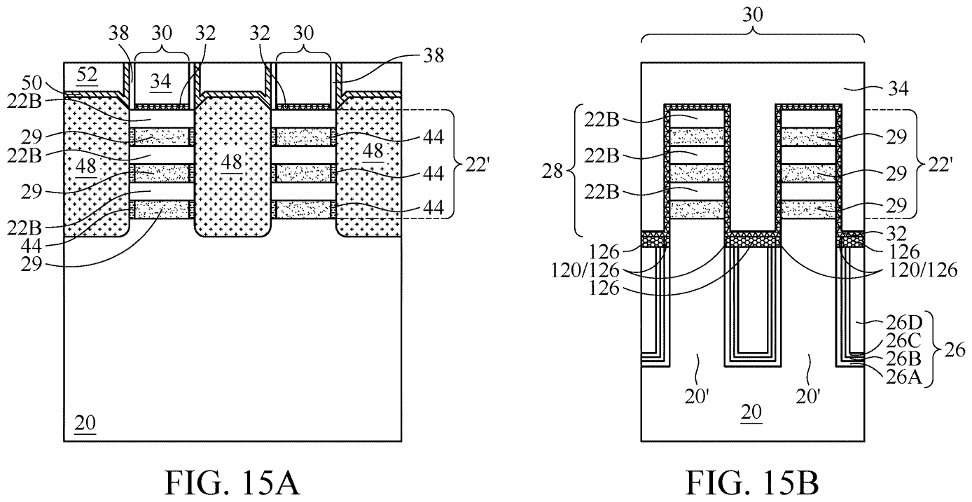

FIGS. 15A and 15B illustrate the cross-sectional views of the structure after the formation of Contact Etch Stop Layer (CESL) 50 and Inter-Layer Dielectric (ILD) 52. The respective process is illustrated as process 232 in the process flow 200 as shown in FIG. 19. FIGS. 15A and 15B illustrate the cross-sections B-B and A2-A2, respectively, in FIG. 9A. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may include silicon oxide, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may result in the removal of hard masks 36 to reveal dummy gate electrodes 34, as shown in FIGS. 15A and 15B. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

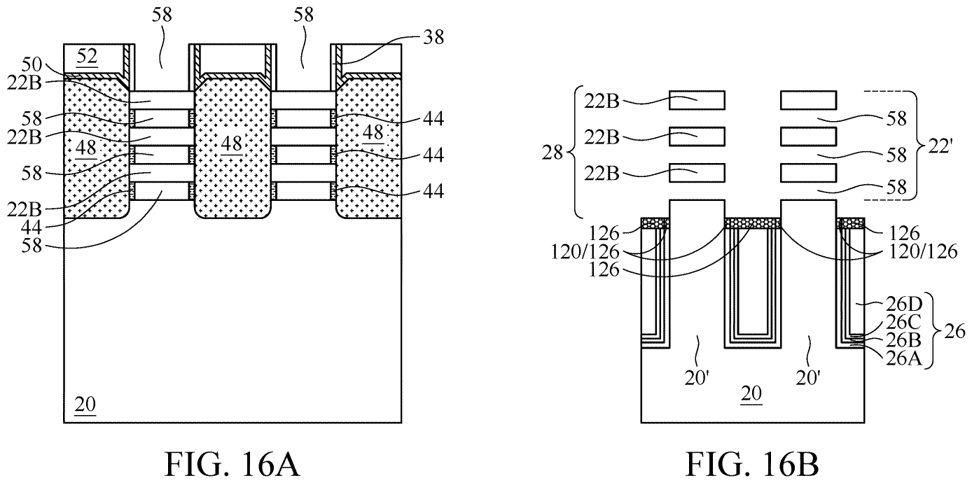

Next, dummy gate electrodes 34 and dummy gate dielectrics 32 (and hard masks 36, if remaining) are removed in one or more etching processes, so that recesses 58 are formed, as shown in FIGS. 16A and 16B. The respective process is illustrated as process 234 in the process flow 200 as shown in FIG. 19. In accordance with some embodiments, dummy gate electrodes 34 and dummy gate dielectrics 32 are removed through an anisotropic dry etch process(es). For example, the etching process may be performed using reaction gas(es) that selectively etch dummy gate electrodes 34 and dummy gate dielectrics 32 at faster rates than ILD 52. Each recess 58 exposes and/or overlies portions of multilayer stacks 22′, which include the future channel regions in subsequently completed transistors.

Disposable interposers 29 are then removed to extend recesses 58 between nanostructures 22B. The respective process is illustrated as process 236 in the process flow 200 as shown in FIG. 19. Disposable interposers 29 may be removed by performing an isotropic etching process such as a wet etching process or a dry etching process using etchants that are selective to the materials of disposable interposers 29, while nanostructures 22B and substrate 20 remain relatively un-etched as compared to disposable interposers 29. In accordance with some embodiments in which disposable interposers 29 include, for example, silicon oxide, the mixture of NF₃ and NH₃, the mixture of HF and NH₃, or HF may be used to remove disposable interposers 29.

In the etching of disposable interposers 29, as shown in FIG. 16B, the STI regions 26 are protected from the etching chemical by protection layer 126, which is not etched (or substantially not etched) due to the high etching selectivity, which is the ratio of the etching rate of disposable interposers 29 to the etching rate of the protection layer 126. For example, the etching selectivity may be greater than about 5, greater than about 10, greater than about 20, or higher. It is appreciated that in the removal of the disposable interposers 29, the remaining portions of dielectric layer 120 (if any is remaining) may be recessed. Due to the small thickness of dielectric layer 120, however, the recessing of dielectric layer 120 is controlled, and the bottom portions of dielectric layer 120 may remain.

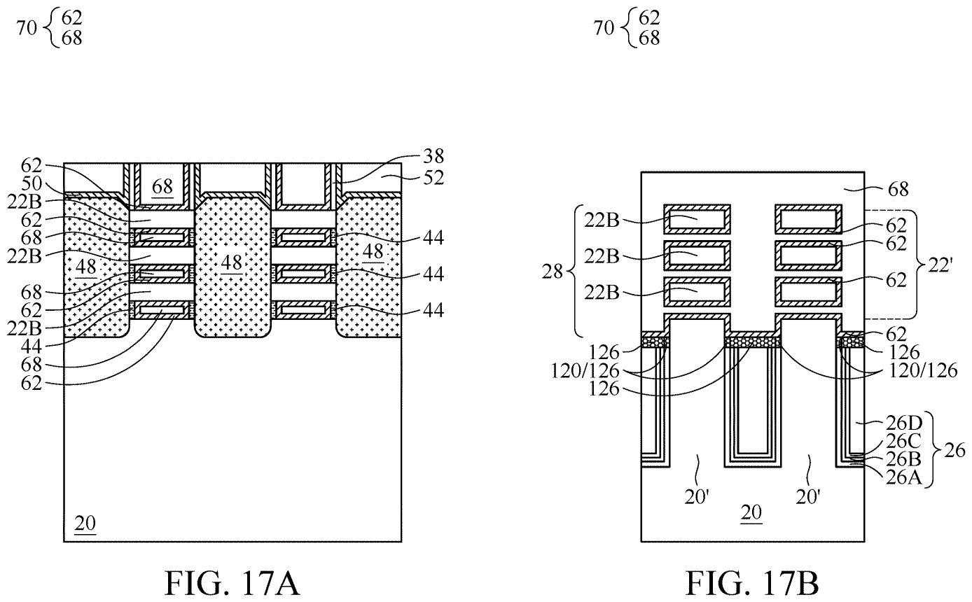

Referring to FIGS. 17A and 17B, gate dielectrics 62 and gate electrodes 68 are formed, hence forming replacement gate stacks 70. The respective process is illustrated as process 238 in the process flow 200 as shown in FIG. 19. In accordance with some embodiments, each of gate dielectric 62 includes an interfacial layer and a high-k dielectric layer over the interfacial layer. The interfacial layer may be formed of or comprises silicon oxide, which may be deposited (or formed through thermal oxidation) through a conformal deposition process such as ALD or CVD, or through an oxidation process. In accordance with some embodiments, the high-k dielectric layers comprise one or more high-k dielectric layers. For example, the high-k dielectric layer(s) may include a metal oxide or a silicate of hafnium, aluminum, zirconium, lanthanum, manganese, barium, titanium, lead, and combinations thereof.

When the interfacial layer is formed through deposition, the top surface of protection layer 126 contacts the bottom surface of the interfacial layer to form interfaces. When the interfacial layer is formed through thermal oxidation, the top surface of protection layer 126 contacts the bottom surface of the high-k dielectric layer to form interfaces.

Gate electrodes 68 are also formed. In the formation process, conductive layers are first formed on the high-k dielectric layer, and the remaining portions of recesses 58 are filled. Gate electrodes 68 may include a metal-containing material such as TiN, TaN, TiAl, TiAlC, cobalt, ruthenium, aluminum, tungsten, combinations thereof, and/or multilayers thereof. For example, gate electrodes 68 may comprise any number of layers, any number of work function layers, and possibly a filling material. Gate dielectrics 62 and gate electrodes 68 also fill the spaces between adjacent ones of nanostructures 22B, and fill the spaces between the bottom ones of nanostructures 22B and the underlying substrate strips 20'.

After the filling of recesses 58, a planarization process such as a CMP process or a mechanical grinding process is performed to remove the excess portions of the gate dielectrics 62 and gate electrodes 68, which excess portions are over the top surface of ILD 52. Gate electrodes 68 and gate dielectrics 62 are collectively referred to as gate stacks 70 of the resulting transistors.

In the processes shown in FIGS. 18A, 18B, and 18C, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52.

As further illustrated by FIGS. 18A, 18B, and 18C, ILD 76 is deposited over ILD 52 and over gate masks 74. An etch stop layer (not shown) may be (or may not be) deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

ILD 76, ILD 52, CESL 50, and gate masks 74 are then etched to form recesses (occupied by contact plugs 80A and 80B) exposing surfaces of source/drain regions 48 and/or gate stacks 70. Although FIG. 18A illustrates that contact plugs 80A and 80B are in a same cross-section, in various embodiments, contact plugs 80A and 80B may be formed in different cross-sections, thereby reducing the risk of shorting with each other.

After the recesses are formed, silicide regions 78 are formed over source/drain regions 48. Contact plugs 80B are then formed over silicide regions 78. Also, contacts 80A (may also be referred to as gate contact plugs) are also formed in the recesses, and are over and contacting gate electrodes 68. The corresponding structure is also shown in FIG. 18A. Transistor 82 is thus formed.

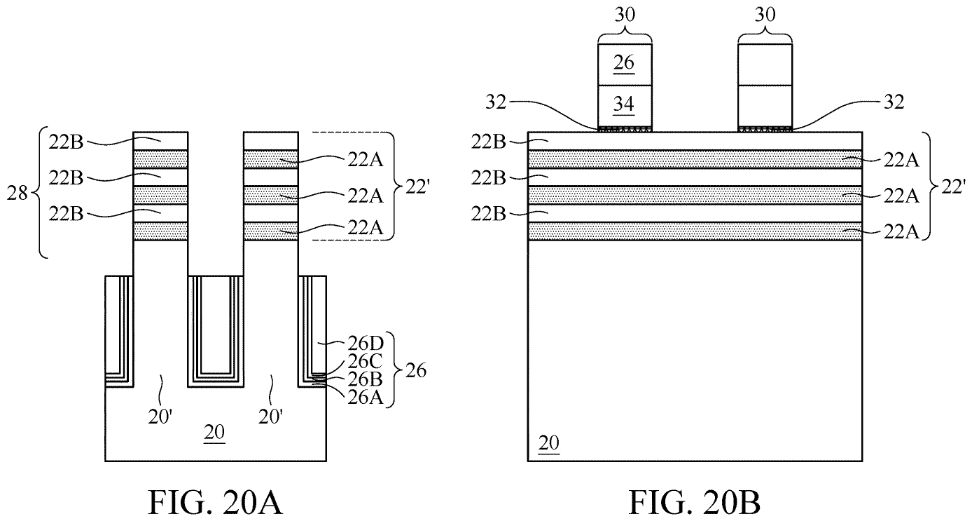

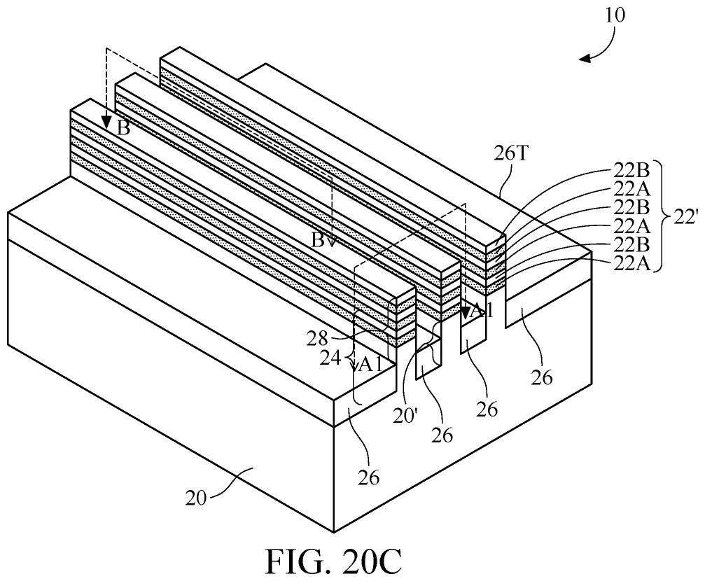

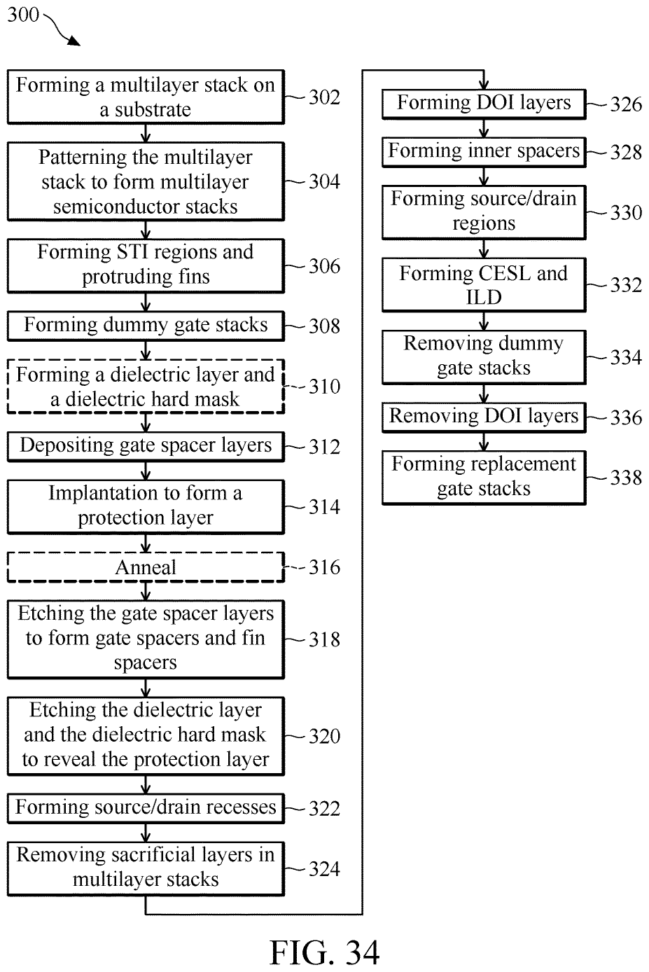

FIGS. 20A, 20B and 20C through FIGS. 33A, 33B, and 33C illustrate views of intermediate stages in the formation of a transistor in accordance with alternative embodiments of the present disclosure. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable. The corresponding process flow is shown in the process flow 300 as shown in FIG. 34.

The initial steps of these embodiments are essentially the same as shown in FIGS. 1 and 2. The respective processes are illustrated as processes 302 and 304 in the process flow 300 as shown in FIG. 34. Next, STI regions 26 and protruding fins are formed, as shown in FIG. 20C. The formation process is essentially the same as discussed referring to FIG. 3A. The respective processes are illustrated as process 306 in the process flow 300 as shown in FIG. 34. FIGS. 20A and 20B illustrate the cross-sections B-B and A1-A1, respectively in FIG. 20C.

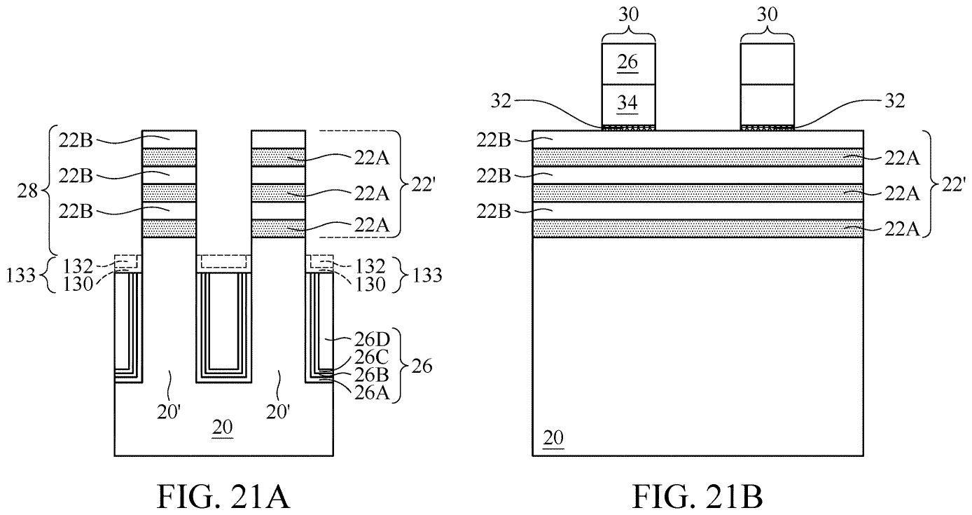

FIGS. 21A and 21B illustrate the formation of dummy gate stacks 30 accordance with some embodiments. The respective process is illustrated as process 308 in the process flow 300 as shown in FIG. 34. The perspective view of the dummy gate stacks 30 are essentially the same as shown in FIG. 9A. The details of the dummy gate stacks 30 are essentially the same as in the preceding embodiments, and are not repeated herein.

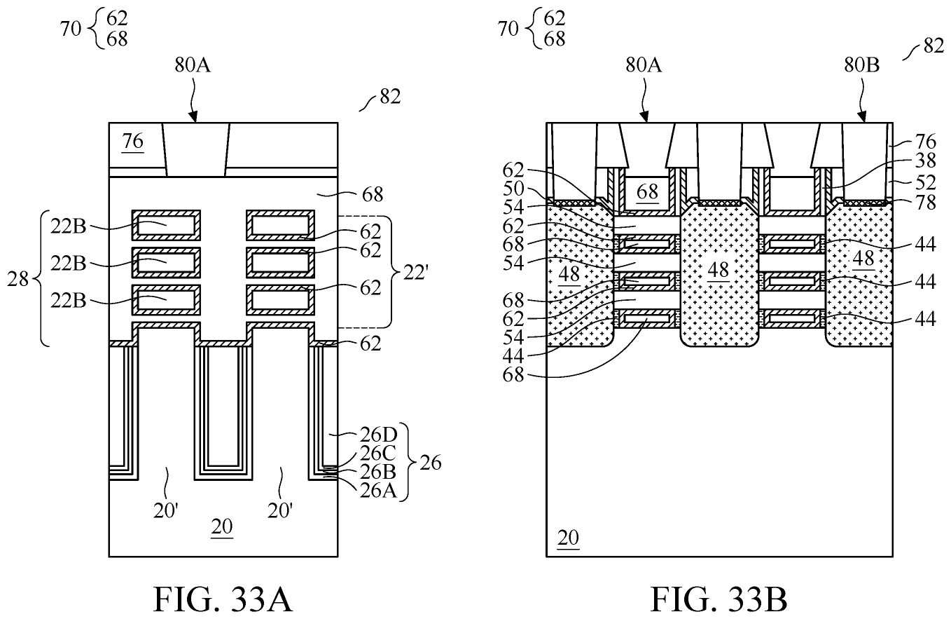

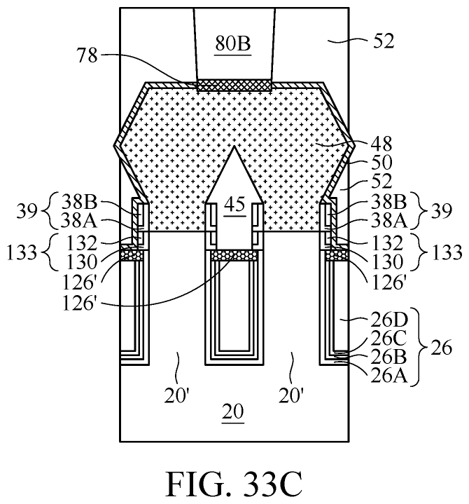

FIGS. 21A and 21B further illustrate the formation of dielectric liner 130 and dielectric hard mask 132 in accordance with some embodiments. The respective process is illustrated as process 310 in the process flow 300 as shown in FIG. 34. In accordance with alternative embodiments, the formation of dielectric liner 130 and dielectric hard mask 132 is skipped, and the subsequently deposited gate spacer layers are in physical contact with the top surfaces of STI regions 26. Accordingly, the process 310 in FIG. 35 is shown as being dashed to indicate that process 310 may be performed or may be skipped. Dielectric liner 130 and dielectric hard mask 132 are also shown as being dashed in FIGS. 21A and 33C to indicate that these features may be or may not be formed.

Dielectric liner 130 and dielectric hard mask 132 (when formed) have materials different from each other, and the candidate materials of each of dielectric liner 130 and dielectric hard mask 132 may be selected from SiO, SiN, SiC, SiCN, SiON, SiOCN, and the like. In accordance with some embodiments, dielectric liner 130 is formed of or comprises silicon oxide, and dielectric hard mask 132 may be formed of or comprises silicon nitride.

The formation of dielectric liner 130 and dielectric hard mask 132 may include depositing a conformal dielectric liner 130 through a conformal deposition process, depositing dielectric hard mask 132, polishing dielectric hard mask 132, etching back dielectric hard mask 132 to the shape as shown in FIG. 20A, and etching the exposed portions of dielectric liner 130.

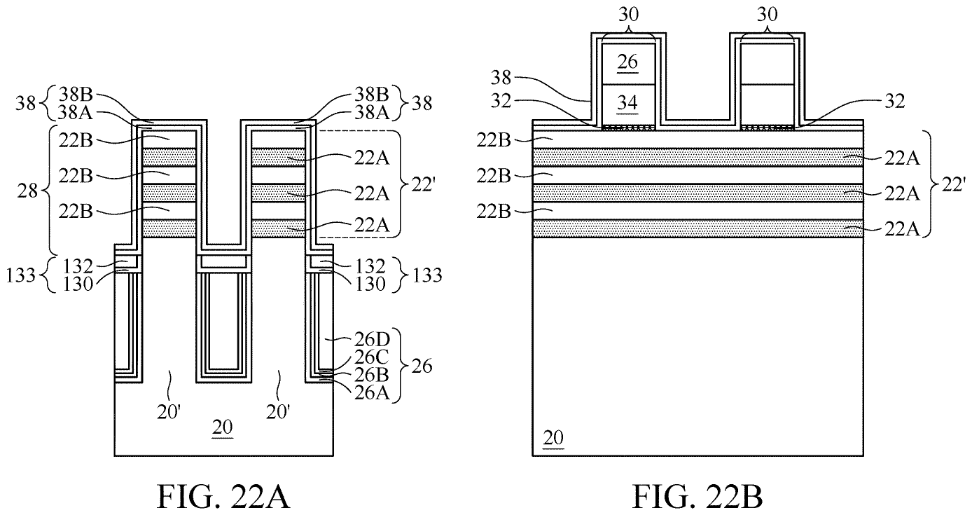

Referring to FIGS. 22A and 22B, gate spacer layers 38 (including 38A and 38B) are formed through deposition processes. The respective process is illustrated as process 312 in the process flow 300 as shown in FIG. 34. The materials of gate spacer layers 38A and 38B are different from each other, and may be selected from SiO, SiN, SiC, SiCN, SiON, SiOCN, and the like. In accordance with some example embodiments, gate spacer layer 38A is formed of or comprises SiN, and gate spacer layer 38B is formed of or comprises SiOCN, while other materials may also be used. The formation may be achieved through conformal deposition processes such as ALD, CVD, or the like.

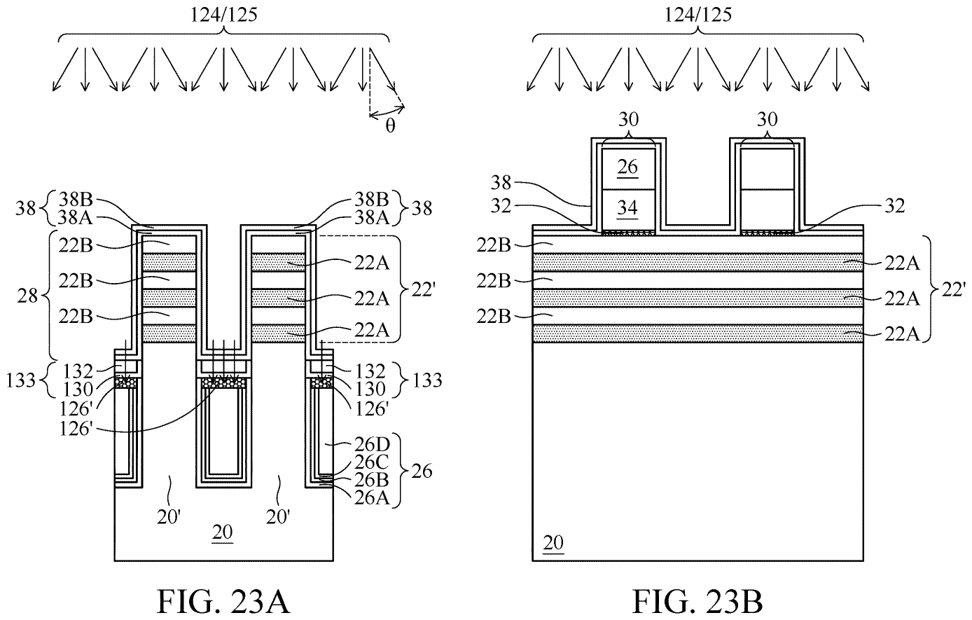

Next, as shown in FIGS. 23A and 23B, implantation process 124 is performed. The respective process is illustrated as process 314 in the process flow 300 as shown in FIG. 34. The implanted species may include carbon and/or nitrogen. In addition, silicon may be implanted. Silicon may be implanted along with carbon and/or nitrogen. The silicon may also be implanted before, after, or in the same implantation process as the implantation of carbon and/or nitrogen. In addition, some other elements such as He, Ar, oxygen, and the like may be implanted, which may be implanted when (or before or after) the Si, C, N, and/or the like are implanted.

It is appreciated that although the implanted species will be implanted into the portions of multilayer stacks 22′ that are not directly under dummy gate stacks 30, these portions of multilayer stacks 22′ will be removed in subsequent processes.

In accordance with some embodiments, the implantation process 124 may be performed through a vertical implantation process and/or a tilt implantation process. When the tilt implantation process is performed, the tilt angle θ may greater than 0 degrees and smaller than about 60 degrees. When the vertical implantation is performed, parts of the gate spacer layers 38A and 38B that will be left in subsequent processes as fin spacers are not implanted since these parts are masked from implantation process 124 by the corresponding overlying portions of gate spacers layers 38A and 38B. Otherwise, when the tilt implantation is performed, the future fin spacers 39 and sidewall spacers 133 are also implanted, and/or have the implanted species diffused into them in subsequent anneal process 125.

In accordance with some embodiments, the thicknesses of gate spacer layers 38A and 38B are greater than the thicknesses of dielectric liners 26B and 26C, and the vertical portions of gate spacer layers 38A and 38B fully overlap the vertical portions of dielectric liners 26B and 26C. Accordingly, when the vertical implantation is performed, the vertical portions of dielectric liner 26A (which may comprise silicon oxide) and dielectric liners 26B and 26C (which may comprise silicon nitride) may not be implanted. The dielectric regions 26D, on the other hand, are implanted.

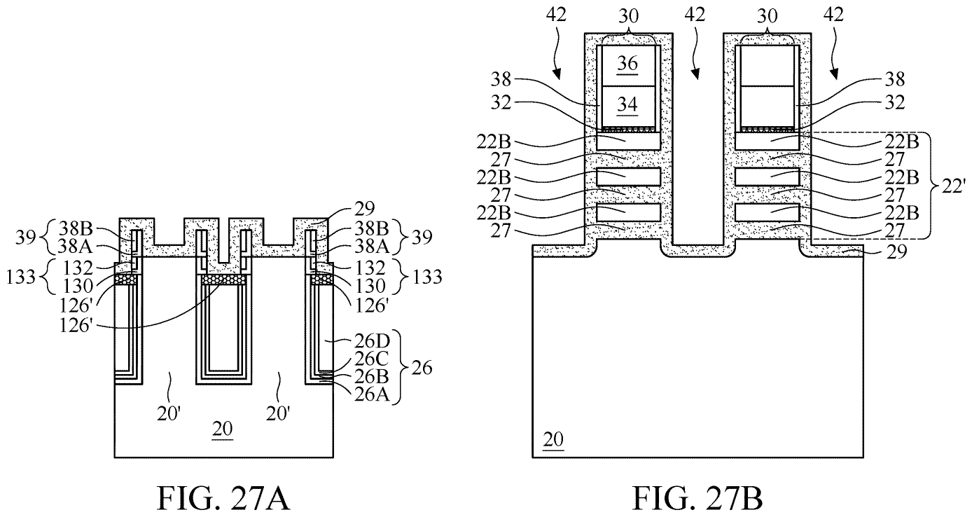

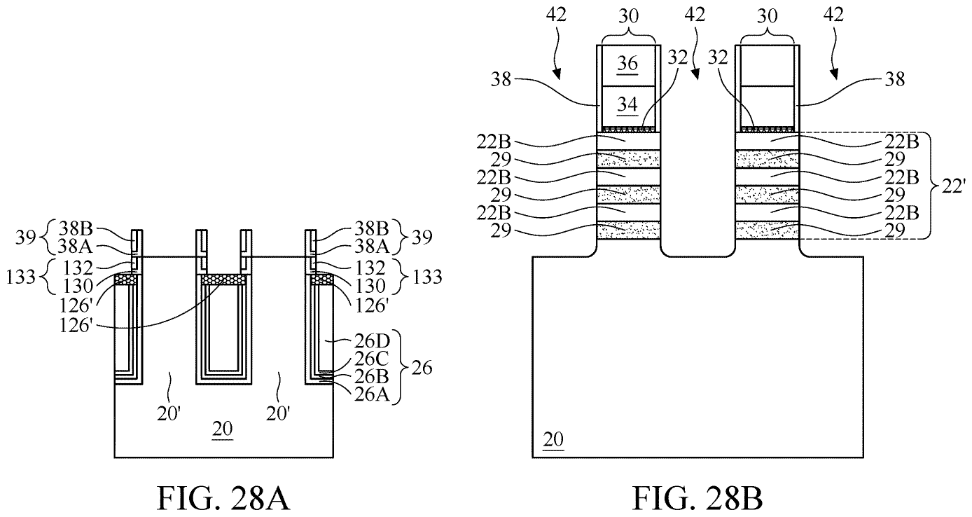

When tilt implantation is performed, dielectric liners 26A, 26B and 26C may be implanted also. Whether to implant the vertical portions of dielectric liners 26A, 26B and 26C may be determined based on whether the original materials of dielectric liners 26A, 26B and 26C (before the implantation process) have high-enough etching selectivity or not (relative to the subsequently formed disposable interposers 29 as shown in FIGS. 27A, 27B, 28A, and 28B) in a subsequent process. The details are discussed in detail in subsequent paragraphs.

As a result of the implantation process 124, the top portions of STI regions 26 are converted as protection layer 126', which has a higher Si, carbon, nitrogen, oxygen, and/or He or Ar concentration (atomic percentages) than before the implantation process 124, and than the underlying un-implanted portions of STI regions 26. Dielectric liner 130 and dielectric hard mask 132 are also implanted, and hence have higher concentration of the implanted elements that un-implanted nearby portions. Depending on the implanted species, the protection layer 126′ may include SiOC, SiON, SiOCN, or the like, with other elements such as He and/or Ar incorporated.

In accordance with some embodiments, the implantation energy is controlled, so that the implanted species penetrate through gate spacer layers 38B and 38A, and into the top portions of STI regions 26. In accordance with some embodiments, the implanted species such as Si, C, N, O, He, and the like may each be implanted with an energy in a range between about 1 keV and about 20 keV. The dosage of each of the above listed species and/or the total dosage of the implanted species may be in the range between about 5E13/cm² and 1E16/cm². The concentration may be in the range between about 1E20/cm³ and about 3E22/cm³.

The implantation process 124 may be performed at room temperature or at an elevated temperature to reduce the damage to the implanted regions. For example, the implantation process 124 may be performed at a temperature in a range between the room temperature (for example, between about 18 °C and about 22 °C) and about 600 °C , and may be in the range between about 50 °C and about 600 °C.

In accordance with some embodiments, after the implantation process 124, an anneal process 125 is performed to recover the structure of the implanted regions, so that the damage caused by the implantation process 124 is reduced or eliminated. The respective process is illustrated as process 316 in the process flow 300 as shown in FIG. 34. When the vertical portions of dielectric liner 26A, 26B and 26C are not implanted due to the masking of the upper structures, the implanted species may be diffused laterally into dielectric liner 26A, 26B and 26C to convert these portions of dielectric liner 26A, 26B and 26C into protection layer 126′.

In accordance with alternative embodiments, the anneal process 125 is not performed, and the recovery of the implanted regions is achieved by subsequent anneal processes such as source/drain anneal process and/or ILD anneal process. The process 316 is thus shown using a dashed box to indicate that process 316 may be performed or may be skipped.

In accordance with some embodiments, the anneal process 125 (if performed) may be performed at a temperature in the range between about 500 °C and about 1,200 °C. The annealing duration may depend on the temperature, and may be in the range between about 1 millisecond and about 2 hours. For example, when a high anneal temperature is adopted such as in the range between about 1,000 °C and about 1,200°, the anneal duration may be short such as in the range between about 1 millisecond and about 2 milliseconds. When a low anneal temperature is adopted such as in the range between about 500 °C and about 600°, the anneal duration may be long such as in the range between about 1 hour and about 2 hours.

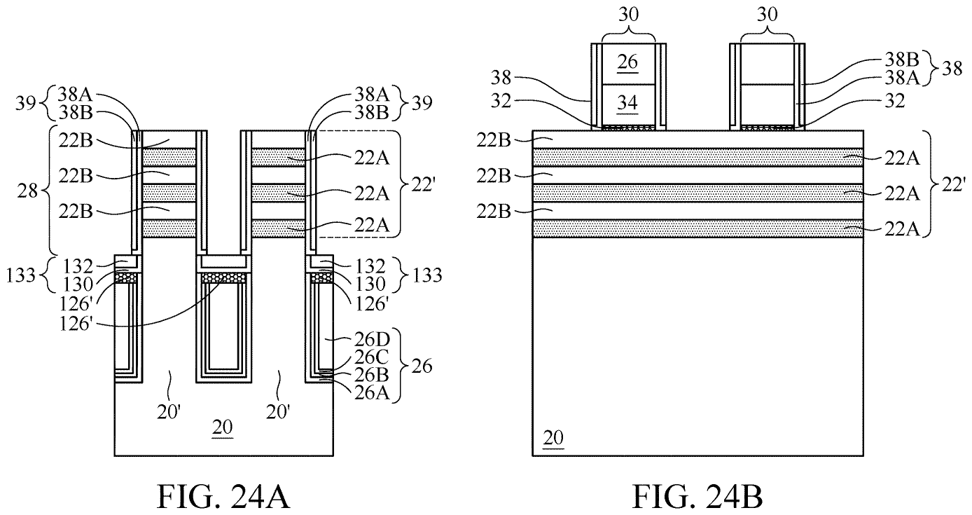

FIGS. 24A and 24B illustrate the etching process for forming gate spacers 38 (FIG. 24B) and fin spacers 39 (FIG. 24A) in accordance with some embodiments. The respective process is illustrated as process 318 in the process flow 300 as shown in FIG. 34. The etching process may comprise performing a first anisotropic etching process to etch gate spacer layer 38B, so that the horizontal portions of the gate spacer layer 38B are removed, and vertical portions of the gate spacer layer 38B are left.

Gate spacer layer 38A is then etched using the remaining portions of gate spacer layer 38B as an etching mask. The remaining portions of the gate spacer layers 38A and 38B on the sidewalls of dummy gate stacks 30 are gate spacers 38. The remaining portions of the gate spacer layers 38A and 38B on the sidewalls of protruding fins 28 are fin spacers 39. In the cross-section as shown in FIG. 24A, dielectric hard mask 132 is exposed.

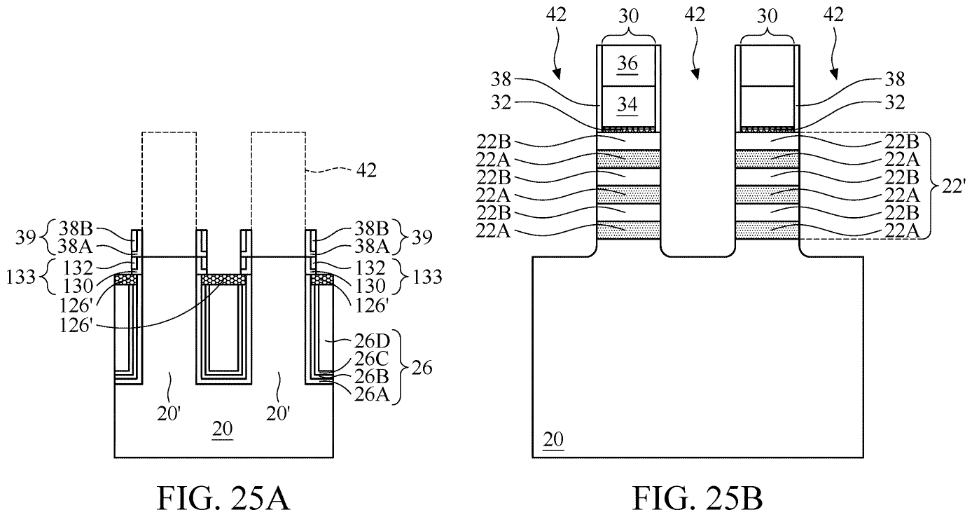

As shown in FIGS. 25A and 25B, dielectric hard mask 132 and the dielectric layer 130 (if formed) are also etched through anisotropic etching processes. The respective process is illustrated as process 320 in the process flow 300 as shown in FIG. 34. As a result, protection layers 126′ are exposed, which are also used as etch stop layers during a subsequent etching process. The remaining portions of dielectric hard mask 132 and dielectric layer 130 also form sidewall spacers 133. In accordance with alternative embodiments, the etching stops on the top surface of dielectric hard mask 132, and dielectric hard mask 132 and dielectric layer 130 are not etched.

During the source/drain recessing process, fin spacers 39 are also shortened. The shortened fin spacers 39 and the remaining portions of sidewall spacers 133 including dielectric hard mask 132 and dielectric layer 130 (if etched) collectively form composite fin spacers, which are at levels higher than protection layers 126′. When dielectric hard mask 132 and dielectric layer 130 are not etched, the implanted dielectric hard mask 132 acts as a protection layer in subsequent processes.

FIGS. 25A and 25B illustrate a source/drain recessing process. The respective process is illustrated as process 322 in the process flow 300 as shown in FIG. 34. The protruding fins 28 that are not directly underlying dummy gate stacks 30 and gate spacers 38 are etched in an anisotropic etching process. The remaining spaces left by the removed protruding fins 28 are referred to as source/drain recesses 42, which are between fin spacers 39. In FIGS. 25A and 25B and subsequent figures, the gate spacer layers 38A and 38B in gate spacers 38 and fin spacers 39 are not illustrated separately.

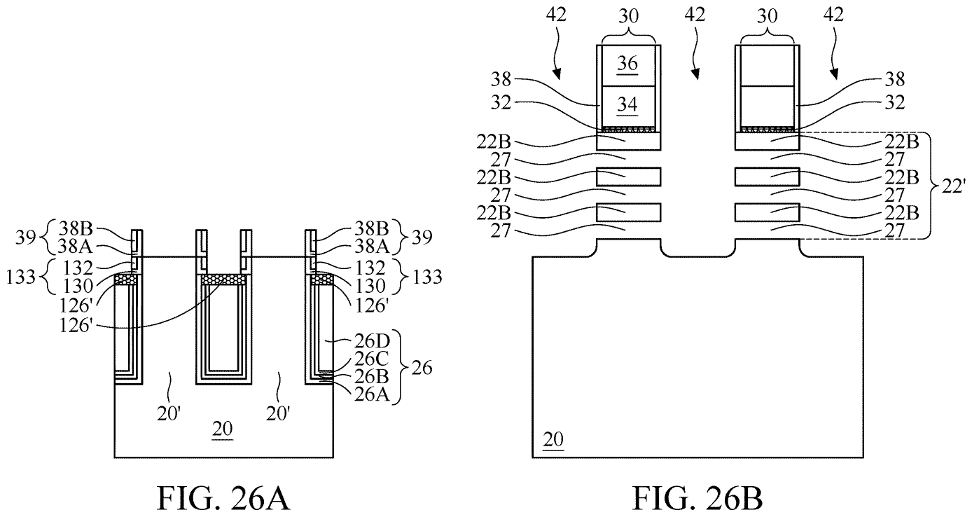

FIGS. 26A, 26B, 27A, 27B, 28A, and 28B illustrate the replacement of sacrificial layers 22A with disposable interposers 29. Referring to FIGS. 26A and 26B, the sacrificial layers 22A are first removed, forming openings 27 between nanostructures 22B. The respective process is illustrated as process 324 in the process flow 300 as shown in FIG. 34.

Referring to FIGS. 27A and 27B, dielectric layer 29 is deposited to fill openings 27. In accordance with some embodiments, dielectric layer 29 comprises an oxide such as silicon oxide, and thus the resulting disposable interposers 29 are referred to as Disposable Oxide Interposers (DOIs) 29. In accordance with other embodiments, other types of oxides may be adopted.

In accordance with some embodiments, dielectric layer 29 is formed through a conformal deposition process such as ALD, CVD, or the like. The deposition process may be performed until openings 27 are fully filled. In accordance with alternative embodiments, the formation of dielectric layer 29 includes a conformal deposition process (such as ALD or CVD) followed by a bottom-up filling process (such as FCVD, spin-on coating or the like) may be performed to fill openings 27 and recesses 42, followed by a planarization process and an anisotropic etching process.

Referring to FIGS. 28A and 28B, an etching process is performed to etch dielectric layer 29. The remaining portions of dielectric layer 29 are also referred to as disposable interposers 29, which are located between nanostructures 22B. The respective process is illustrated as process 326 in the process flow 300 as shown in FIG. 34. In accordance with some embodiments in which the dielectric layer 29 is formed through a conformal deposition process, a trimming process, which may include an isotropic etching process may be performed. When dielectric layer 29 is formed through a conformal process followed by a bottom-up deposition process, the etching process may include an anisotropic etching process, followed by a light isotropic etching process.

With the proceeding of the etching process, the underlying regions including protection layer 126′ (FIG. 28A) is exposed. It is appreciated that if protection layer 126′ is not formed, STI regions 26 may be exposed to the etching chemical used for etching dielectric layer 29. Due to the implantation process as discussed precedingly, protection layer 126′ is formed over STI regions 26.

Protection layer 126′ has a high etching selectivity relative to disposable interposers 29. The etching selectivity, which is the ratio of the etching rate of dielectric layer 29 to the etching rate of protection layer 126′, may be greater than about 5, and may be in the range between about 5 and 20. For example, when a diluted HF solution (with one part of HF in 100 parts of water, for example) is used, the etching selectivity may be about 6. With the high etching selectivity, protection layer 126′ protects STI regions 26 from being etched by the etching chemical used for etch dielectric layer 29. As a comparison, the un-implanted dielectric region 26D (if protection layer 126′ is not formed) would have been exposed to the etching chemical, and may have the same etching rate as dielectric layer 29, making STI regions 26 prone to damage in the formation of disposable interposers 29.

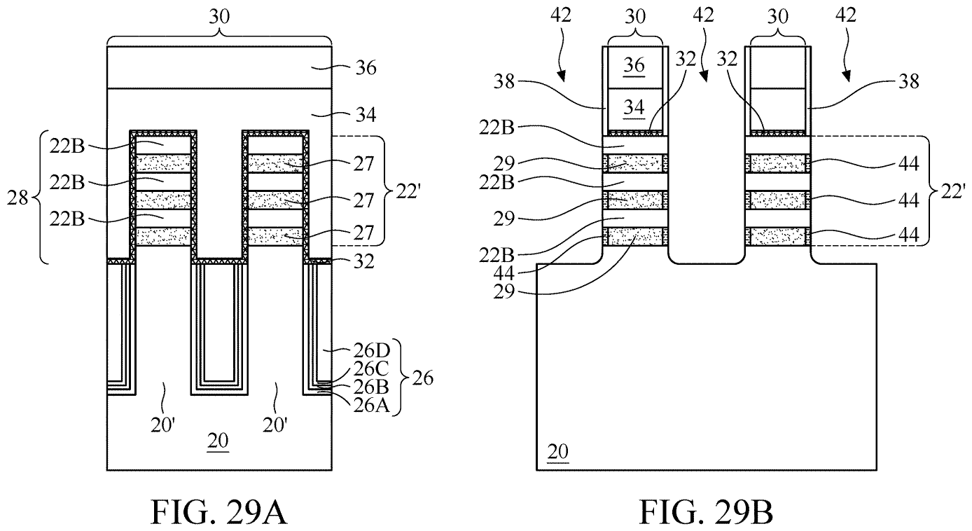

Referring to FIGS. 29A and 29B, disposable interposers 29 are laterally recessed to form inner spacers 44 (FIG. 29B). The respective process is illustrated as process 328 in the process flow 300 as shown in FIG. 34. FIGS. 29A and 29B illustrate essentially the same cross-sections as the cross-sections A2-A2 and B-B as shown in FIG. 9A. The lateral recessing of disposable interposers 29 may be achieved through a wet etching process or a dry etching process. The wet etching process may be performed using a dip process, a spray process, a spin-on process, or the like. Nanostructures 22B are not etched.

Inner spacers 44 are then formed. In accordance with some embodiments, the formation of inner spacers 44 includes depositing a conformal dielectric layer, which extends into the lateral recesses, followed by a trimming process to remove the portions of the dielectric layer outside of the lateral recesses. The remaining portions of the dielectric layer are referred to as inner spacers 44.

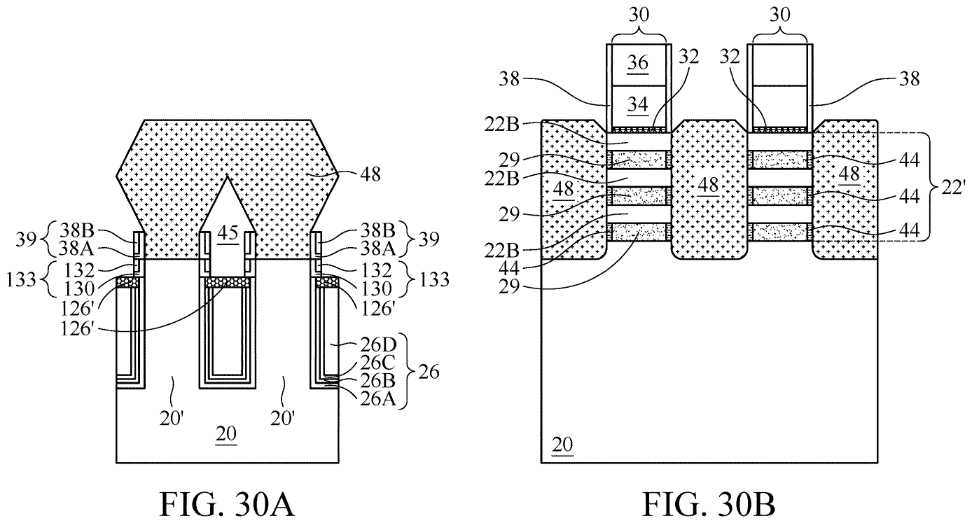

Referring to FIGS. 30A and 30B, epitaxial source/drain regions 48 are formed in recesses 42 through selective epitaxy. The respective process is illustrated as process 330 in the process flow 300 as shown in FIG. 34. FIGS. 30A and 30B illustrate the cross-sections B-B and A2-A2, respectively, in FIG. 9A. Depending on whether the resulting transistor is a p-type transistor or an n-type transistor, a p-type or an n-type impurity may be in-situ doped with the proceeding of the epitaxy. For example, when the resulting transistor is a p-type Transistor, silicon germanium boron (SiGeB), silicon boron (SiB), or the like may be grown. Conversely, when the resulting transistor is an n-type Transistor, silicon phosphorous (SiP), silicon arsenic (SiAs), silicon carbon phosphorous (SiCP), or the like may be grown.

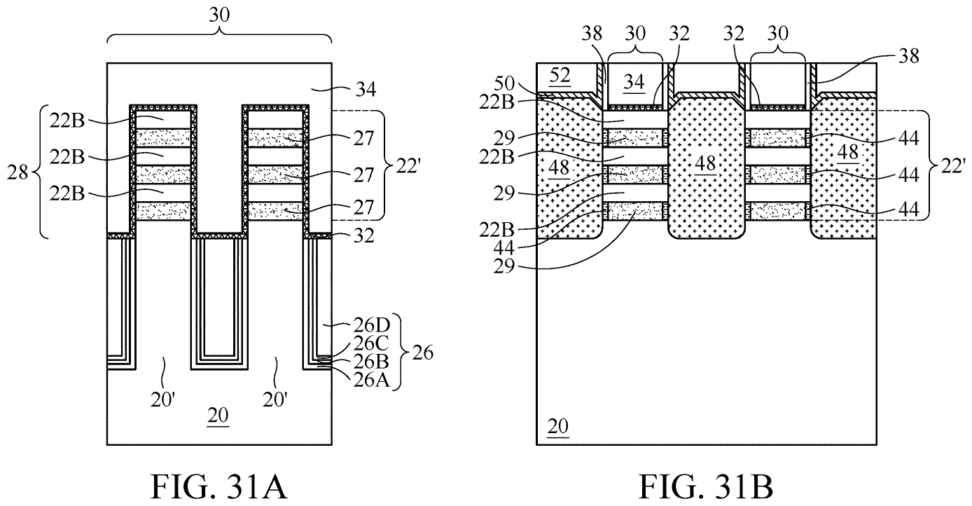

FIGS. 31A and 31B illustrate the cross-sectional views of the structure after the formation of Contact Etch Stop Layer (CESL) 50 and Inter-Layer Dielectric (ILD) 52. The respective process is illustrated as process 332 in the process flow 300 as shown in FIG. 34. FIGS. 31A and 31B illustrate the cross-sections essentially the same as the cross-sections B-B and A2-A2, respectively, in FIG. 9A.

CESL 50 and ILD 52 are planarized through a planarization process such as a CMP process or a mechanical grinding process. In accordance with some embodiments, the planarization process may remove hard masks 36 to reveal dummy gate electrodes 34, as shown in FIGS. 31A and 31B. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

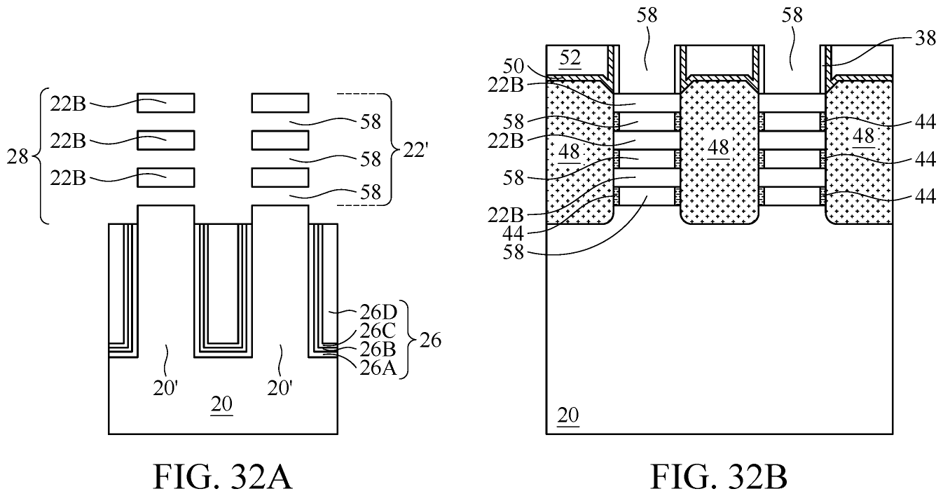

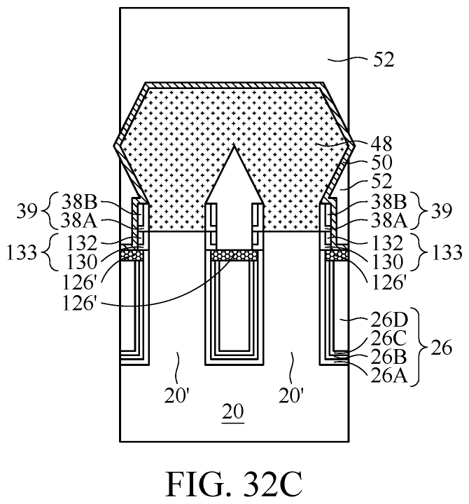

Next, dummy gate electrodes 34 and dummy gate dielectrics 32 (and hard masks 36, if remaining) are removed in one or more etching processes, so that recesses 58 are formed, as shown in FIGS. 32A, 32B, and 32C. The respective process is illustrated as process 334 in the process flow 300 as shown in FIG. 34. In accordance with some embodiments, dummy gate electrodes 34 and dummy gate dielectrics 32 are removed through an anisotropic dry etch process(es). For example, the etching process may be performed using reaction gas(es) that selectively etch dummy gate electrodes 34 and dummy gate dielectrics 32 at faster rates than ILD 52. Each recess 58 exposes and/or overlies portions of multilayer stacks 22′, which include the future channel regions in subsequently completed transistors.

Disposable interposers 29 are then removed to extend recesses 58 between nanostructures 22B. The respective process is illustrated as process 336 in the process flow 300 as shown in FIG. 34. Disposable interposers 29 may be removed by performing an isotropic etching process such as a wet etching process using etchants that are selective to the materials of disposable interposers 29, while nanostructures 22B and substrate 20 remain relatively un-etched as compared to disposable interposers 29. In accordance with some embodiments in which disposable interposers 29 include, for example, silicon oxide, the mixture of NF₃ and NH₃, the mixture of HF and NH₃, and HF may be used to remove disposable interposers 29.

Referring to FIGS. 33A, 33B, and 33C, gate dielectrics 62 and gate electrodes 68 are formed, hence forming replacement gate stacks 70. The respective process is illustrated as process 338 in the process flow 300 as shown in FIG. 34. In accordance with some embodiments, each of gate dielectric 62 includes an interfacial layer and a high-k dielectric layer on the interfacial layer. The interfacial layer may be formed of or comprises silicon oxide, which may be deposited through a conformal deposition process such as ALD or CVD, or through an oxidation process.

In accordance with some embodiments, the high-k dielectric layers comprise one or more high-k dielectric layers. For example, the high-k dielectric layer(s) may include a metal oxide or a silicate of hafnium, aluminum, zirconium, lanthanum, manganese, barium, titanium, lead, and combinations thereof.

Gate electrodes 68 are also formed. In the formation, conductive layers are first formed on the high-k dielectric layer, and the remaining portions of recesses 58 are filled. Gate electrodes 68 may include a metal-containing material such as TiN, TaN, TiAl, TiAlC, cobalt, ruthenium, aluminum, tungsten, combinations thereof, and/or multilayers thereof. For example, gate electrodes 68 may comprise any number of layers, any number of work function layers, and possibly a filling material. Gate dielectrics 62 and gate electrodes 68 also fill the spaces between adjacent ones of nanostructures 22B, and fill the spaces between the bottom ones of nanostructures 22B and the underlying substrate strips 20'.

After the filling of recesses 58, a planarization process such as a CMP process or a mechanical grinding process is performed to remove the excess portions of the gate dielectrics 62 and gate electrodes 68, which excess portions are over the top surface of ILD 52. Gate electrodes 68 and gate dielectrics 62 are collectively referred to as gate stacks 70 of the resulting transistors.

FIGS. 33A, 33B, and 33C also illustrate subsequent processes for forming more features. For example, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52.

ILD 76 is deposited over ILD 52 and over gate masks 74. ILD 76, ILD 52, CESL 50, and gate masks 74 are then etched to form recesses (occupied by contact plugs 80A and 80B) exposing surfaces of source/drain regions 48 and/or gate stacks 70. Silicide regions 78 are formed over source/drain regions 48. Contact plugs 80B are then formed over silicide regions 78. Also, contacts 80A (may also be referred to as gate contact plugs) are also formed in the recesses, and are over and contacting gate electrodes 68. The corresponding structure is also shown in FIG. 18A. Transistor 82 is thus formed.

As shown in FIG. 33A, gate dielectric 62 is in physical contact with the top surface of STI regions 26, and protection layer 126′ does not extend directly underlying gate stack 70. FIG. 33C illustrates that protection layer 126′ is directly underlying source/drain region 42, and may be exposed to the air gap 45, which is sealed by neighboring portions of source/drain region 42.

The embodiments of the present disclosure have some advantageous features. In accordance with some embodiments, by forming a protection layer on top of the STI regions, in the removal of the disposable interposers, the protection layer protects the STI regions from being recessed in accordance with some embodiments. The undesirable increase in the parasitic capacitance between gate electrodes and semiconductor strips is thus reduced. In accordance with other embodiments, the protection layer is formed through an implantation process performed on dielectric spacer layers. The corresponding protection layer has the function of protecting the underlying STI regions during the formation of disposable interposers.

In accordance with some embodiments of the present disclosure, a method comprises forming a shallow trench isolation region aside of a protruding fin, wherein the protruding fin comprises a first semiconductor nanostructure and a second semiconductor nanostructure; forming a dielectric layer on the shallow trench isolation region; forming a dummy gate stack over the protruding fin; performing an implantation process to form a protection layer, wherein the protection layer covers the shallow trench isolation region; removing a sacrificial layer in the protruding fin to leave a space between the first semiconductor nanostructure and the second semiconductor nanostructure; forming a disposable interposer in the space; removing the dummy gate stack; performing an etching process to remove the disposable interposer; and forming a replacement gate stack, wherein a portion of the replacement gate stack is filled in the space.

In an embodiment, the etching process is performed using an etching chemical, and wherein when the disposable interposer is removed, the protection layer separates the etching chemical from the shallow trench isolation region. In an embodiment, the dielectric layer is deposited before the dummy gate stack is formed, and wherein a portion of the dielectric layer between the protruding fin and a neighboring protruding fin is implanted to form the protection layer. In an embodiment, the protection layer further comprises a top portion of the shallow trench isolation region.

In an embodiment, the protection layer comprises a portion directly underlying the dummy gate stack. In an embodiment, after the replacement gate stack is formed, the protection layer comprises a portion directly underlying the replacement gate stack. In an embodiment, the dielectric layer comprises a gate spacer layer, and the method further comprises, after the implantation process, etching the gate spacer layer to form gate spacers. In an embodiment, during the implantation process, the dummy gate stack acts as an implantation mask to prevent a region directly underlying the dummy gate stack from being implanted.

In an embodiment, in the implantation process, an element selected from the group consisting of silicon, carbon, nitrogen, helium, and combinations thereof is implanted. In an embodiment, in the implantation process, the element selected from the group consisting of carbon, nitrogen, and combinations thereof is implanted. In an embodiment, in the implantation process, silicon is implanted. In an embodiment, the method further comprises, after the implantation process, performing an anneal process.

In accordance with some embodiments of the present disclosure, a structure comprises a semiconductor strip; a first semiconductor nanostructure overlapping, and spaced apart from, the semiconductor strip; a shallow trench isolation region contacting an edge of the semiconductor strip; a gate stack comprising a first portion between the first semiconductor nanostructure and the semiconductor strip, wherein the gate stack comprises a gate dielectric and a gate electrode over the gate dielectric; and a protection layer between the shallow trench isolation region and the gate stack, wherein the protection layer comprises a dielectric material different from materials of the shallow trench isolation region and the gate dielectric.

In an embodiment, the shallow trench isolation region comprises a dielectric liner and a dielectric region over the dielectric liner, and wherein the protection layer contacts top surface of both of the dielectric liner and the dielectric region. In an embodiment, the protection layer comprises silicon oxynitride, and the shallow trench isolation region comprise silicon oxide.

In an embodiment, the structure further comprises a dielectric layer between, and in contact with, the protection layer and the semiconductor strip, wherein the dielectric layer comprises a different dielectric material than the protection layer. In an embodiment, the dielectric layer comprises silicon oxide. In an embodiment, the structure further comprises a source/drain region aside of the gate stack, wherein the protection layer comprises a part directly under the source/drain region.

In accordance with some embodiments of the present disclosure, a structure comprises a semiconductor substrate; a shallow trench isolation region in the semiconductor substrate, wherein a portion of the semiconductor substrate is aside of and contacts the shallow trench isolation region to act as a semiconductor strip; a semiconductor layer over the semiconductor strip; a gate stack over and encircling the semiconductor layer; a source/drain region aside of the gate stack; and a dielectric protection layer over the shallow trench isolation region, wherein the dielectric protection layer comprises a first portion directly underlying the gate stack, and a second portion directly underlying the source/drain region.

In an embodiment, the dielectric protection layer has a higher atomic percentage of an element than the shallow trench isolation region, and wherein the element is selected from the group consisting of carbon, nitrogen, and combinations thereof.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a dielectric isolation region on a side of a semiconductor region;
forming a gate stack over the semiconductor region;
depositing a gate spacer layer over the gate stack and the semiconductor region;
performing an implantation process on the gate spacer layer;
etching the gate spacer layer to form a gate spacer, with the gate spacer being on a sidewall of the gate stack;
removing a sacrificial layer under the semiconductor region to leave a space;
depositing a disposable interposer layer comprising a portion in the space; and
etching the disposable interposer layer to form a disposable interposer in the space, wherein at an ending time the disposable interposer layer is etched, a top portion of the dielectric isolation region is exposed to a chemical used for etching the disposable interposer layer, and a first etching rate of the dielectric isolation region is lower than a second etching rate of the disposable interposer layer.

2. The method of claim 1 further comprising replacing the gate stack and the disposable interposer with a replacement gate stack.

3. The method of claim 1, wherein in the implantation process, the top portion of the dielectric isolation region is implanted to form a protection layer.

4. The method of claim 1, wherein silicon is implanted by the implantation process.

5. The method of claim 1, wherein carbon is implanted by the implantation process.

6. The method of claim 1, wherein the implantation process comprises a tilt implantation process.

7. A method comprising:
forming a shallow trench isolation region on a side of a protruding fin, wherein the protruding fin comprises a first semiconductor nanostructure and a second semiconductor nanostructure over the first semiconductor nanostructure;
forming a dummy gate stack over the protruding fin;
depositing a gate spacer layer over the dummy gate stack and the protruding fin;
performing an implantation process to convert a top portion of the shallow trench isolation region as a protection layer;
performing an anisotropic etching process on the gate spacer layer to form a gate spacer on a sidewall of the dummy gate stack;
removing a sacrificial layer in the protruding fin to leave a space between the first semiconductor nanostructure and the second semiconductor nanostructure;
depositing a disposable interposer layer, wherein a part of the disposable interposer layer fills the space;
etching the disposable interposer layer to leave a disposable interposer in the space;
removing the dummy gate stack;
removing the disposable interposer from the space; and
forming a replacement gate stack, wherein a portion of the replacement gate stack is filled in the space.

8. The method of claim 7, wherein at an end time the disposable interposer layer is etched, the protection layer is exposed to an etching chemical used for etching the disposable interposer layer.

9. The method of claim 7, wherein when the disposable interposer is removed, the protection layer separates an etching chemical for removing the disposable interposer from an underlying portion of the shallow trench isolation region.

10. The method of claim 7, wherein during the implantation process, the dummy gate stack acts as an implantation mask to prevent a region directly underlying the dummy gate stack from being implanted.

11. The method of claim 10, wherein in the implantation process, an element selected from the group consisting of silicon, carbon, nitrogen, helium, and combinations thereof is implanted.

12. The method of claim 11, wherein in the implantation process, the element selected from the group consisting of carbon, nitrogen, and combinations thereof is implanted.

13. The method of claim 11, wherein in the implantation process, silicon is implanted.

14. The method of claim 7 further comprising, after the implantation process, performing an anneal process.

15. A method comprising:
forming a shallow trench isolation region on a side of a protruding fin, wherein the protruding fin comprises a semiconductor nanostructure;
forming a dummy gate stack over the protruding fin;
depositing a gate spacer layer over the dummy gate stack and the protruding fin;
performing an implantation process on the gate spacer layer, wherein a dopant penetrates through the gate spacer layer, and is implanted into a top portion of the shallow trench isolation region to form a protection layer;
performing an anisotropic etching process on the gate spacer layer to form a gate spacer;
removing the dummy gate stack;
performing an etching process to remove a disposable interposer, so that a bottom surface of the semiconductor nanostructure is exposed to space that is underlying the semiconductor nanostructure; and
forming a replacement gate stack, wherein a portion of the replacement gate stack is filled in the space.

16. The method of claim 15 further comprising:
replacing a sacrificial layer underlying the semiconductor nanostructure with the disposable interposer.

17. The method of claim 16, wherein the sacrificial layer is replaced with the disposable interposer at a time after the gate spacer is formed.

18. The method of claim 15, wherein in the implantation process, an element selected from the group consisting of silicon, carbon, nitrogen, helium, and combinations thereof is implanted.

19. The method of claim 18, wherein in the implantation process, the element selected from the group consisting of carbon, nitrogen, and combinations thereof is implanted.

20. The method of claim 18, wherein in the implantation process, silicon is implanted.
